(19) United States
(12) Patent Application Publication
(10) Pub. No.: US 2024/0213282 A1
(43) Pub. Date: Jun. 27, 2024

(54) LIGHT DETECTION DEVICE AND ELECTRONIC APPARATUS

(71) Applicant: SONY SEMICONDUCTOR SOLUTIONS CORPORATION, Kanagawa (JP)

(72) Inventors: Yuta KUSHIDA, Kanagawa (JP); Kyohei MIZUTA, Kanagawa (JP); Atsushi TODA, Kanagawa (JP)

(73) Assignee: SONY SEMICONDUCTOR SOLUTIONS CORPORATION, Kanagawa (JP)

(21) Appl. No.: 18/554,040

(22) PCT Filed: Mar. 4, 2022
(86) PCT No.: PCT/JP2022/009423

§ 371 Date: Oct. 5, 2023

(30) Foreign Application Priority Data
Apr. 15, 2021 (JP) 2021-069278

(51) Int. Cl. H01L 27/146; G02B 5/30

(52) U.S. Cl. CPC H01L 27/1461; G02B 5/3058; H01L 27/14612; H01L 27/14627

(57) ABSTRACT

A light detection device capable of supplementing a sensitivity drop includes: a semiconductor layer having a photoelectric conversion area; and an optical element supplying light having a polarization plane according to an arrangement direction of the opening parts. The optical element includes a first area in which the opening parts are arranged in a first direction and a second area in which the opening parts are arranged in a second direction. A light incidence face of a first photoelectric conversion area includes a plurality of concave parts arranged at a first angle with the first direction or a groove extending in this direction, and an uneven part of a second photoelectric conversion area includes a plurality of concave parts at the first angle with the second direction or a groove extending in this direction.

### TECHNICAL FIELD

The present technology (a technology relating to the present disclosure) relates to a light detection device and an electronic apparatus and, more particularly, to a light detection device and an electronic apparatus having an optical element such as a wire grid polarizer or the like.

### BACKGROUND ART

An imaging apparatus having a plurality of imaging elements in which a wire grid polarizer (WGP) is disposed are known, for example, from PTL 1. A photoelectric conversion area that is included in a photoelectric conversion unit disposed in an imaging element and generates a current on the basis of incident light, for example, is formed from a charge coupled device (CCD) element or a complementary metal oxide semiconductor (CMOS) image sensor. A wire grid polarizer is disposed on a light incident face side of the photoelectric conversion unit, and, for example, a plurality of light reflection layers of a band shape, insulating layers, and light absorption layers are separately aligned and formed.

### CITATION LIST

### Patent Literature

PTL 1: JP 2012-238632A

### SUMMARY

### Technical Problem

The wire grid polarizer causes only polarized light that is transmissive-axis light out of polarized light that is extinction-axis light and polarized light that is transmissive-axis light to be transmitted through it. For this reason, in a case in which a light detection device includes a wire grid polarizer, only polarized light that is transmissive-axis light out of light incident in the light detection device is supplied to the photoelectric conversion area. For this reason, a light detection device including a wire grid polarizer has a light quantity smaller than a light detection device having no wire grid polarizer, and thus lowering of the sensitivity is unavoidable.

An object of the present technology is to provide a light detection device and an electronic apparatus capable of compensating for sensitivity lowering.

### Solution to Problem

A light detection device according to one aspect of the present technology including a semiconductor layer having a photoelectric conversion area; and an optical element including a base material and a plurality of opening parts disposed in the base material and having a groove shape passing through the base material in a thickness direction, selecting light having a polarization plane along an arrangement direction of the opening parts, supplying the selected light to the photoelectric conversion area, and disposed to overlap the photoelectric conversion area in a plan view, in which the opening parts are aligned in a longitudinal direction and are disposed to be separated from each other in a transverse direction, the optical element includes a first area in which the opening parts are arranged in a first direction and a second area in which the opening parts are arranged in a second direction different from the first direction, a light incidence face of the semiconductor layer has a plurality of uneven parts, a first uneven part that is the uneven part included in a first photoelectric conversion area that is the photoelectric conversion area overlapping the first area in the plan view includes a plurality of concave parts arranged in a direction forming a first angle with the first direction or grooves extending in this direction, and a second uneven part that is the uneven part included in a second photoelectric conversion area that is the photoelectric conversion area overlapping the second area in the plan view includes a plurality of concave parts arranged in a direction forming the first angle with the second direction or grooves extending in this direction.

An electronic apparatus according to another aspect of the present technology including the light detection device described above; and an optical system configured to form an image of image light from a subject in the light detection device.

### BRIEF DESCRIPTION OF DRAWINGS

FIG. 1 is a chip layout diagram illustrating one configuration example of a light detection device according to a first embodiment of the present technology.

FIG. 2 is a block diagram illustrating one configuration example of the light detection device according to the first embodiment of the present technology.

FIG. 3 is an equivalent circuit diagram of a pixel of the light detection device according to the first embodiment of the present technology.

FIG. 4 is a longitudinal cross-sectional view illustrating a cross-sectional structure of a pixel of the light detection device according to the first embodiment of the present technology.

FIG. 5A is a horizontal cross-sectional view illustrating arrangement of four photoelectric conversion areas and a relative relation between a photoelectric conversion area and a wire grid polarizer taken along cut-out line B-B illustrated in FIG. 4.

FIG. 5B is a longitudinal cross-sectional view illustrating a part of a wire grid polarizer taken along cut-out line C-C illustrated in FIG. 5A.

FIG. 5C is a conceptual diagram for describing light and the like passing through the wire grid polarizer of the light detection device according to the first embodiment of the present disclosure.

FIG. 6 is a horizontal cross-sectional view illustrating arrangement of four photoelectric conversion areas and a relative relation between a photoelectric conversion area and an uneven part taken along cut-out line A-A illustrated in FIG. 4.

FIG. 7 is a diagram illustrating a comparative example of an uneven part in an extending direction of a groove.

FIG. 8 is a diagram illustrating a relation between quantum efficiency and an angle.

FIG. 9A is a process cross-sectional view illustrating a method of manufacturing the light detection device according to the first embodiment of the present technology.

FIG. 9B is a process cross-sectional view continuing FIG. 9A.

FIG. 9C is a process cross-sectional view continuing FIG. 9B.

FIG. 9D is a process cross-sectional view continuing FIG. 9C.

FIG. 9E is a process cross-sectional view continuing FIG. 9D.

FIG. 9F is a process cross-sectional view continuing FIG. 9E.

FIG. 9G is a process cross-sectional view continuing FIG. 9F.

FIG. 9H is a process cross-sectional view continuing FIG. 9G.

FIG. 9I is a process cross-sectional view continuing FIG. 9H.

FIG. 9J is a process cross-sectional view continuing FIG. 9I.

FIG. 9K is a process cross-sectional view continuing FIG. 9J.

FIG. 10 is a plan view of an uneven part included in the light detection device according to Modified Example 1 of the first embodiment of the present technology.

FIG. 11 is a plan view of an uneven part included in a light detection device according to Modified Example 2 of the first embodiment of the present technology.

FIG. 12 is a plan view of an uneven part included in a light detection device according to Modified Example 3 of the first embodiment of the present technology.

FIG. 13 is a plan view of an uneven part included in a light detection device according to Modified Example 4 of the first embodiment of the present technology.

FIG. 14 is a plan view of an uneven part included in a light detection device according to a second embodiment of the present technology.

FIG. 15 is a plan view of an uneven part included in a light detection device according to Modified Example 1 of the second embodiment of the present technology.

FIG. 16 is a plan view of an uneven part included in a light detection device according to Modified Example 2 of the second embodiment of the present technology.

FIG. 17 is a plan view of an uneven part included in a light detection device according to Modified Example 3 of the second embodiment of the present technology.

FIG. 18A is a longitudinal cross-sectional view illustrating a cross-sectional structure of a pixel included in a light detection device according to Modified Example 4 of the second embodiment of the present technology.

FIG. 18B is a horizontal cross-sectional view illustrating arrangement of four photoelectric conversion areas and a relative relation between a photoelectric conversion area and an uneven part taken along cut-out line A-A illustrated in FIG. 18A.

FIG. 19 is a horizontal cross-sectional view illustrating a relative relation between an uneven part included in a light detection device according to another form of Modified Example 4 of the second embodiment of the present technology and a photoelectric conversion area.

FIG. 20 is a longitudinal cross-sectional view illustrating a cross-sectional structure of a pixel of a light detection device according to a third embodiment of the present technology.

FIG. 21 is a horizontal cross-sectional view illustrating a relative relation between a photoelectric conversion area and a wire grid polarizer taken along cut-out line B-B illustrated in FIG. 20.

FIG. 22 is a horizontal cross-sectional view illustrating a relative relation between a photoelectric conversion area and an uneven part taken along cut-out line A-A illustrated in FIG. 20.

FIG. 23 is a diagram illustrating a schematic configuration of an electronic apparatus according to a fourth embodiment of the present technology.

### DESCRIPTION OF EMBODIMENTS

Hereinafter, preferable embodiments for implementing the present technology will be described with reference to the drawings. The embodiments which will be described below show an example of a representative embodiment of the present technology, and the scope of the present technology should not be narrowly interpreted on the basis of this.

In the illustration of the drawings, the same or similar portions are denoted with the same or similar reference signs. However, it should be noted that the drawings are schematic, and the relationship between thicknesses and planar dimensions, the ratio between thicknesses of respective layers, and the like, may be different from actual ones. Therefore, specific thicknesses and dimensions should be determined by considering the following descriptions. In addition, the drawings include portions where dimensional relationships and ratios differ between the drawings in some cases.

In addition, the following first to fourth embodiments exemplifies devices and methods for embodying the technical ideas of the present technology, and the technical ideas of the present technology are not meant to specify that materials, shapes, structures, arrangement, and the like of component parts are those described below. The technical ideas of the present technology can be variously modified within the technical scope described in the claims.

Description will be given in the following order.
1. First Embodiment
2. Second Embodiment
3. Third Embodiment
4. Fourth Embodiment

### First Embodiment

In this first embodiment, an example in which the present technology is applied to a light detection device that is a rear-face emission type complementary metal oxide semiconductor (CMOS) image sensor will be described.

### <<Entire Configuration of Light Detection Device>>

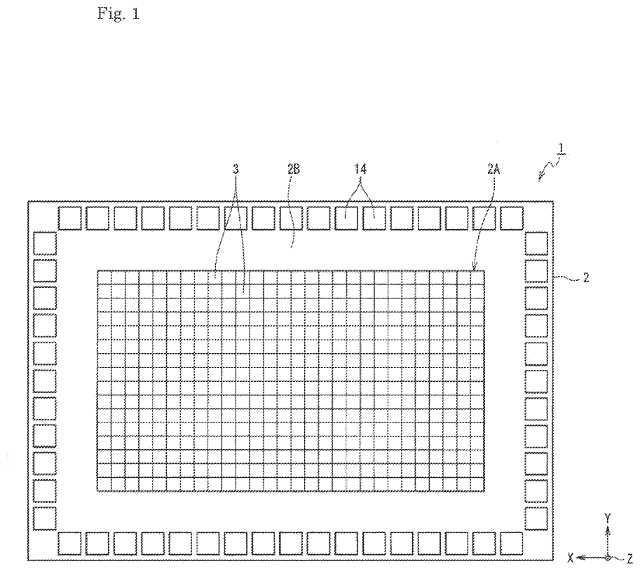

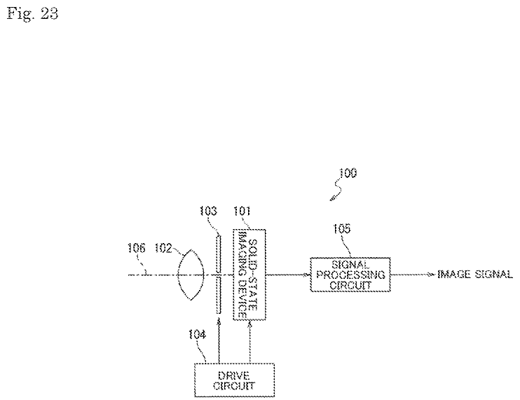

First, the entire configuration of a light detection device 1 will be described. As illustrated in FIG. 1, the light detection device 1 according to the first embodiment of the present technology is configured using semiconductor chips 2 of which a two-dimensional planar shape in the plan view is a rectangular shape in a plan view. In other words, the light detection device 1 is mounted in the semiconductor chip 2. As illustrated in FIG. 23, this light detection device 1 takes in image light (incident light 106) from a subject through an optical system (an optical lens) 102, converts a light quantity of incident light 106 formed as an image on an imaging surface into an electric signal in units of pixels, and outputs the electric signal as a pixel signal.

As illustrated in FIG. 1, the semiconductor chip 2 in which the light detection device 1 is mounted has a pixel region 2A of a rectangular shape disposed in a center part and a peripheral region 2B disposed on an outer side of this pixel region 2A to surround the pixel region 2A on a two-dimensional plane including an X direction and a Y direction intersecting with each other.

The pixel region 2A, for example, is a light receiving face receiving light condensed by the optical system 102 illustrated in FIG. 23. In the pixel region 2A, a plurality of pixels 3 are disposed in a matrix pattern in a two-dimensional plane including the X direction and the Y direction. In other words, the pixels 3 are repeatedly disposed in respect directions of the X direction and the Y direction intersecting with each other inside a two-dimensional plane. In this embodiment, as an example, the X direction and the Y direction are orthogonal to each other. In addition, a direction that is orthogonal to both the X direction and the Y direction is a Z direction (a thickness direction).

As illustrated in FIG. 1, a plurality of bonding pads 14 are disposed in the peripheral region 2B. Each of the plurality of bonding pads 14, for example, is disposed along one side among four sides in the two-dimensional plane of the semiconductor chip 2. Each of the plurality of bonding pads 14 is an input/output terminal used when the semiconductor chip 2 is electrically connected to an external device.

### <Logic Circuit>

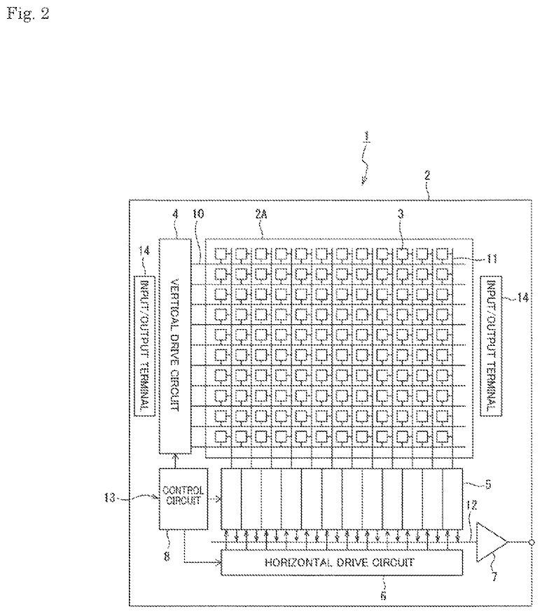

As illustrated in FIG. 2, the semiconductor chip 2 includes a logic circuit 13 that includes a vertical drive circuit 4, a column signal processing circuit 5, a horizontal drive circuit 6, an output circuit 7, a control circuit 8, and the like. The logic circuit 13, for example, is configured by complementary MOS (CMOS) circuits having metal oxide semiconductor field effect transistors (MOSFET) of an n-channel conduction type and MOSFETs of a p-channel conduction type as field effect transistors.

For example, the vertical drive circuit 4 is constituted of a shift register. The vertical drive circuit 4 sequentially selects a desired pixel drive line 10, supplies a pulse for driving the pixels 3 to the selected pixel drive line 10, and drives respective pixels 3 in unit of rows. In other words, the vertical drive circuit 4 sequentially performs selective scanning of the pixels 3 of the pixel region 2A in units of rows in a vertical direction and supplies a pixel signal from the pixel 3 based on signal electric charge generated in accordance with a received light quantity by the photoelectric conversion element of each pixel 3 to the column signal processing circuit 5 through a vertical signal line 11.

The column signal processing circuit 5, for example, is disposed in each column of the pixels 3 and performs signal processing such as noise elimination or the like for each pixel column on signals output from the pixels 3 corresponding to one row. For example, the column signal processing circuit 5 performs signal processing such as correlated double sampling (CDS) for eliminating a pixel-specific fixed pattern noise, analog digital (AD) conversion, and the like. A horizontal selection switch (not illustrated) is connected and disposed between an output storage of the column signal processing circuit 5 and the horizontal signal line 12.

For example, the horizontal drive circuit 6 is constituted of a shift register. The horizontal drive circuit 6 sequentially selects each column signal processing circuit 5 by sequentially outputting a horizontal scanning pulse to the column signal processing circuit 5 and outputs a pixel signal on which signal processing has been performed from each column signal processing circuit 5 to the horizontal signal line 12.

The output circuit 7 performs signal processing on the pixel signals sequentially supplied from the respective column signal processing circuits 5 through the horizontal signal line 12 and outputs resultant pixel signals. As the signal processing, for example, buffering, black level adjustment, a column deviation correction, various types of digital signal processing, and the like can be used.

The control circuit 8 generates a clock signal or a control signal as a reference for operations of the vertical drive circuit 4, the column signal processing circuit 5, the horizontal drive circuit 6, and the like on the basis of a vertical synchronization signal, a horizontal synchronization signal, and a master clock signal. In addition, the control circuit 8 outputs the generated clock signal or control signal to the vertical drive circuit 4, the column signal processing circuit 5, the horizontal drive circuit 6, and the like.

### <Pixel>

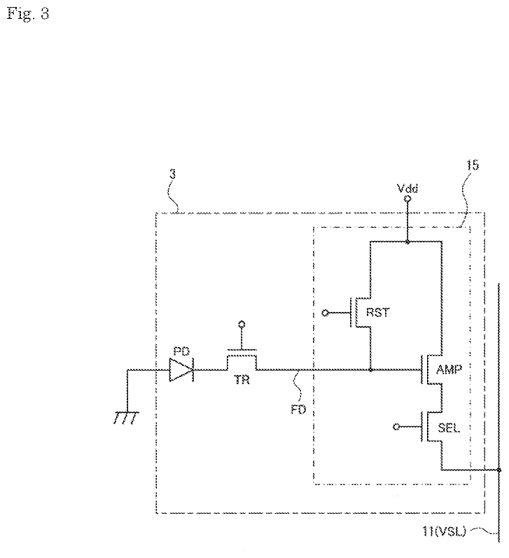

FIG. 3 is an equivalent circuit diagram illustrating one configuration example of the pixel 3. The pixel 3 includes a photoelectric conversion element PD, an electric charge accumulation area (floating diffusion) FD accumulating (holding) signal electric charge acquired through photoelectric conversion using this photoelectric conversion element PD, and a transfer transistor TR that transmits signal electric charge acquired through photoelectric conversion using this photoelectric conversion element PD to the electric charge accumulation area FD. In addition, the pixel 3 includes a reading circuit 15 that is electrically connected to the electric charge accumulation area FD.

The photoelectric conversion element PD generates signal electric charge corresponding to a light reception amount. In addition, the photoelectric conversion element PD temporarily accumulates (holds) the generated signal electric charge. The photoelectric conversion element PD has a cathode side electrically connected to a source region of the transfer transistor TR and an anode side electrically connected to a reference electric potential line (for example, the ground). As the photoelectric conversion element PD, for example, a photodiode is used.

A drain region of the transfer transistor TR is electrically connected to the electric charge accumulation area FD, a gate electrode of the transfer transistor TR is electrically connected to a transfer transistor drive line among pixel drive lines 10 (see FIG. 2).

The electric charge accumulation area FD temporarily accumulates and holds signal electric charge transmitted from the photoelectric conversion element PD through the transfer transistor TR.

The reading circuit 15 reads signal electric charge accumulated in the electric charge accumulation area FD and outputs a pixel signal based on signal electric charge. The reading circuit 15 includes, for example, an amplification transistor AMP, a selection transistor SEL, and a reset transistor RST as pixel transistors but is not limited thereto. Such a transistor (AMP, SEL, RST), for example, is configured by a MOSFET including a gate insulating film formed from an oxide silicon film (a SiO2 film), a gate electrode, and one pair of main electrode regions functioning as a source region and a drain region. In addition, such a transistor may be a metal insulator semiconductor FET (MISFET) in which a gate insulating film is formed from a nitride silicon film (a Si3N4 film) or a laminated film of a nitride silicon film, an oxide silicon film, and the like.

The amplification transistor AMP has a source region electrically connected to a drain region of the selection transistor SEL and a drain region electrically connected to a power source line Vdd and a drain region of the reset transistor. The gate electrode of the amplification transistor AMP is electrically connected to the electric charge accumulation area FD and a source region of the reset transistor RST.

In the selection transistor SEL, a source region is electrically connected to the vertical signal line 11 (VSL), and a drain is electrically connected to the source region of the amplification transistor AMP. A gate electrode of the selection transistor SEL is electrically connected to a selection transistor drive line among pixel drive lines 10 (see FIG. 2).

In the reset transistor RST, a source region is electrically connected to the electric charge accumulation area FD and the gate electrode of the amplification transistor AMP, and a drain region is electrically connected to the power source line Vdd and the drain region of the amplification transistor AMP. A gate electrode of the reset transistor RST is electrically connected to a reset transistor drive line among the pixel drive lines 10 (see FIG. 2).

### <<Specific Configuration of Light Detection Device>>

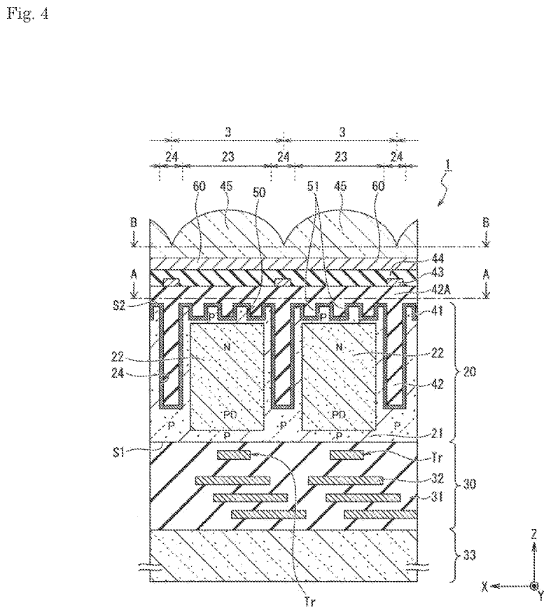

Next, a specific configuration of the light detection device 1 will be described with reference to FIG. 4.

### <Lamination Structure of Light Detection Device>

As illustrated in FIG. 4, the light detection device 1 includes a semiconductor layer 20 that has a first face S1 and a second face S2 positioned on opposite sides. The semiconductor layer 20 is composed of a monocrystalline silicon substrate of a first conduction type, for example, a p type. In addition, the light detection device 1 includes a multilayer wiring layer 30, which includes an interlayer insulating film 31 and a wiring layer 32, and a support substrate 33 that are sequentially stacked on the first face S1 side of the semiconductor layer 20. In addition, the light detection device 1 includes members such as a pinning layer 41, an insulating film 42A, a light shielding layer 43, a planarization film 44, a wire grid polarizer 60 that is an optical element, a micro-lens (an on-chip lens) 45, and the like that are sequentially stacked on the second face S2 side of the semiconductor layer 20. In addition, the light detection device 1 includes an uneven part 50 disposed in a photoelectric conversion area 23 to be described below. At least a part of incident light incident in the light detection device 1 sequentially passes through the micro-lens 45, the wire grid polarizer 60, the planarization film 44, the insulating film 42A, the pinning layer 41, and the semiconductor layer 20 among the constituent elements described above. In addition, the first face S1 of the semiconductor layer 20 may be referred to as an element formation face or a principal face, and the second face S2 side may be referred to as a light incidence face or a rear face.

### <Wire Grid Polarizer>

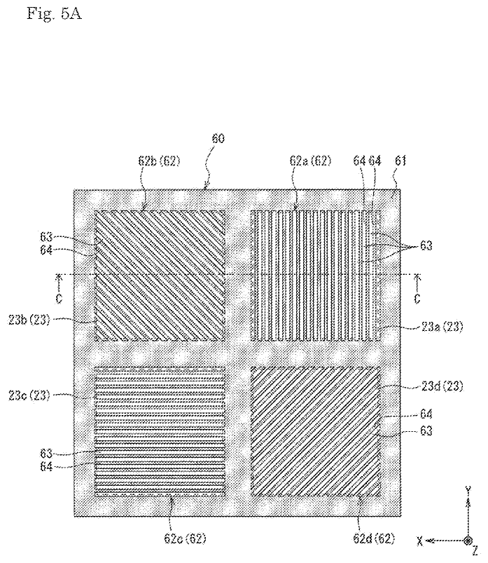

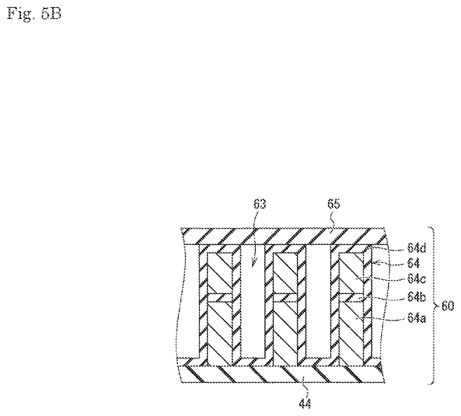

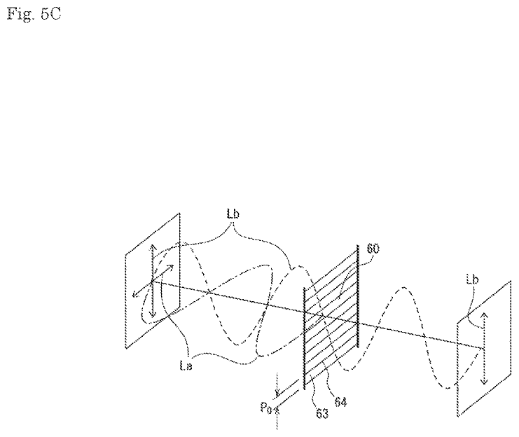

FIG. 5A is a horizontal cross-sectional view illustrating a cross-section structure taken along cut-out line B-B illustrated in FIG. 4, and FIG. 4 is a longitudinal cross-sectional view taken along cut-out line C-C illustrated in FIG. 5A. As illustrated in FIG. 5A, the wire grid polarizer 60 includes a base material 61 and a plurality of grooves 63 that are arranged in the base material 61 and pass through the base material 61 in a thickness direction and is an optical element that selects light having a polarization plane along the arrangement direction of the grooves 63, supplies the selected light to the photoelectric conversion area 23, and is disposed to overlap the photoelectric conversion area 23 in the plan view. The grooves 63 are opening parts of a groove form.

The grooves 63 are formed in a groove formation area 62 of the base material 61. In other words, the groove formation area 62 of the base material 61 has a plurality of grooves 63 arranged at an equal pitch. Inside the groove formation area 62, the grooves 63 are aligned in a longitudinal direction and are disposed to be separated from each other in a transverse direction. In the groove formation area 62, between two grooves 63 adjacent to each other, a band-shaped conductor 64 formed from the base material 61 is included. The band-shaped conductors 64 are aligned in a longitudinal direction and are arranged at an equal pitch with being separate in a transverse direction.

The wire grid polarizer 60 has a plurality of types of groove formation areas 62 in which the arrangement directions of the grooves 63 (the band-shaped conductors 64) are different. For example, the wire grid polarizer 60 includes a first area in which the grooves 63 are disposed in a first direction and a second area in which the grooves 63 are disposed in a second direction different from the first direction. FIG. 5A illustrates an example in which, for example, the wire grid polarizer 60 has four types of groove formation areas 62 (groove formation areas 62a, 62b, 62c, and 62d). An arrangement direction of grooves 63 (band-shaped conductors 64) of the groove formation area 62a is a direction along an X direction. An arrangement direction of grooves 63 (band-shaped conductors 64) of the groove formation area 62b is a direction along a direction of 45 degrees with respect to the X direction. An arrangement direction of grooves 63 (band-shaped conductors 64) of the groove formation area 62c is a direction along a direction of 90 degrees with respect to the X direction. An arrangement direction of grooves 63 (band-shaped conductors 64) of the groove formation area 62d is a direction along a direction of 135 degrees with respect to the X direction. Here, as an example, the first area is assumed to be the groove formation area 62a, and the second area is assumed to be the groove formation area 62b in description. As illustrated in FIG. 5A, the arrangement direction (a second direction) of the grooves 63 disposed in the groove formation area 62b is a direction different from the arrangement direction (a first direction) of the grooves 63 disposed in the groove formation area 62a. In addition, in a case in which the arrangement direction of the grooves 63 (the band-shaped conductors 64) does not need to be identified, the groove formation areas 62a, 62b, 62c, and 62d will not be identified from each other and be simply referred to as a groove formation area 62.

In addition, the wire grid polarizer 60 is disposed to overlap the photoelectric conversion area 23 in the plan view. More specifically, the wire grid polarizer 60 is disposed such that the groove formation area 62 overlaps the photoelectric conversion area 23 in the plan view. As illustrated in FIG. 4, in a thickness direction (the Z direction), the wire grid polarizer 60 does not overlap the semiconductor layer 20.

As illustrated in FIG. 5C, an arrangement pitch PO of the grooves 63 (band-shaped conductors 64) is formed to be significantly smaller than an effective wavelength of incident electromagnetic waves. The wire grid polarizer 60 reflects polarized light La (extinction-axis light), which is parallel to the band-shaped conductor 64, of incident light and transmits polarized light Lb (transmissive-axis light) perpendicular to the band-shaped conductor 64. Thus, the wire grid polarizer 60 functions as a polarizer that transmits only light of a specific direction. The four types of the groove formation areas 62a, 62b, 62c, and 62d described above have the grooves 63 arranged in mutually-different directions and thus transmit polarized light of mutually-different directions. In addition, the wire grid polarizer 60 has features of having a high extinction ratio and high heat resistance and being able to respond to a high wavelength region relative to a resin polarizer. In order to inhibit a transmitted polarized light loss, the wire grid polarizer 60 contains a metal material having high reflectivity.

The base material 61 includes a material composing a light reflection layer 64a to be described below, a material composing an insulating layer 64b, and a material composing a light absorption layer 64c. More specifically, the base material 61 includes films, which are formed from such materials, being stacked. Among such materials, the material composing the light reflection layer 64a is disposed closest to the photoelectric conversion area 23. In addition, the material composing the light reflection layer 64a and the material composing the light absorption layer 64c are metals.

As illustrated in FIG. 5B, the band-shaped conductor 64 has a configuration in which the light reflection layer 64a, the insulating layer 64b, and the light absorption layer 64c are stacked in this order. The light reflection layer 64a is stacked on a face of a side opposite to a face of the insulating film 42A side of the planarization film 44. In addition, the band-shaped conductor 64 includes a protection layer 64d on an outer periphery of the light reflection layer 64a, the insulating layer 64b and the light absorption layer 64c that are stacked.

The light reflection layer 64a reflects incident light. This light reflection layer 64a can be composed using metal having conductivity. Here, examples of the metal composing the light reflection layer 64a include metal materials such as aluminum (Al), silver (Ag), gold (Au), copper (Cu), platinum (Pt), molybdenum (Mo), chromium (Cr), titanium (Ti), nickel (Ni), tungsten (W), iron (Fe), silicon (Si), germanium (Ge), tellurium (Te), and tantalum (Ta) and alloy materials containing these metals.

The light absorption layer 64c absorbs incident light. Examples of materials composing the light absorption layer 64c include a metal material and an alloy material having a non-zero extinction coefficient k, in other words, having a light absorption action and, more specifically, metal materials such as aluminum (Al), silver (Ag), gold (Au), copper (Cu), platinum (Pt), molybdenum (Mo), chromium (Cr), titanium (Ti), nickel (Ni), tungsten (W), iron (Fe), silicon (Si), germanium (Ge), tellurium (Te), and tin (Sn) and alloy materials containing these metals. In addition, examples of the materials include silicide-based materials such as FeSi2 (particularly, β-FeSi2), MgSi2, NiSi2, BaSi2, CrSi2, and CoSi2. Particularly, by using aluminum or an alloy thereof or a semiconductor material including β-FeSi2, germanium and tellurium as the material composing the light absorption layer 64c, high contrast (an appropriate extinction ratio) can be acquired in a visible light region. In addition, in order to have a polarization characteristic in a wavelength region other than visible light, for example, an infrared region, as the material composing the light absorption layer 64c, it is preferable to use silver (Ag), copper (Cu), gold (Au), or the like. This is because resonance wavelengths of these metals are in the vicinity of an infrared region.

The insulating layer 64b, for example, is an insulating material composed of an oxide silicon film. This insulating layer 64b is disposed between the light reflection layer 64a and the light absorption layer 64c.

The protection layer 64d protects the light reflection layer 64a, the insulating layer 64b, and the light absorption layer 64c that are stacked in order. This protection layer 64d, for example, can be composed of an oxide silicon film.

In addition, the wire grid polarizer 60 includes a planarization film 65 stacked on an end-part side that is on a side opposite to an end part of the planarization film 44 side in the band-shaped conductor 64. The planarization film 65, for example, may be composed of an oxide silicon film.

### <Photoelectric Conversion Area>

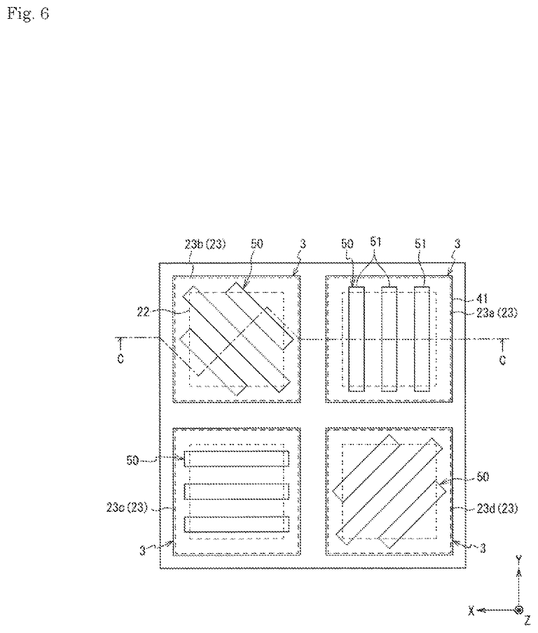

FIG. 6 is a horizontal cross-sectional view illustrating a cross-section structure taken along cut-out line A-A illustrated in FIG. 4, and the part of the semiconductor layer 20 illustrated in FIG. 4 is a longitudinal cross-sectional view illustrating a cross-section structure taken along cut-out line C-C illustrated in FIG. 6. As illustrated in FIGS. 4 and 6, the semiconductor layer 20 has a photoelectric conversion area (an element formation area) 23 having an island shape partitioned by an isolation area 42. This photoelectric conversion area 23 is disposed for each pixel 3. In addition, the number of pixels 3 is not limited to that illustrated in FIG. 6. The isolation area 42 is not limited thereto and, for example, may have a trench structure in which an isolation groove 24 is formed in the semiconductor layer 20, and an insulating film is embedded inside this isolation groove 24.

As illustrated in FIG. 4, the photoelectric conversion area 23 includes a semiconductor region (a well region) 21 of a first conduction type, for example, the p type and a semiconductor region (a photoelectric conversion section) 22 of a second conduction type, for example, the n type embedded inside of the well region 21. The photoelectric conversion element PD illustrated in FIG. 3 is configured in the photoelectric conversion area 23. The photoelectric conversion area 23 performs photoelectric conversion of incident light and generates signal electric charge.

As illustrated in FIG. 5A, in the photoelectric conversion area 23, a photoelectric conversion area overlapping the groove formation area 62a in the plan view will be referred to as photoelectric conversion area 23a for distinguishment from the other photoelectric conversion area. Similarly, in the photoelectric conversion area 23, a photoelectric conversion area overlapping the groove formation area 62b in the plan view will be referred to as a photoelectric conversion area 23b, a photoelectric conversion area overlapping the groove formation area 62c in the plan view will be referred to as a photoelectric conversion area 23c, and a photoelectric conversion area overlapping the groove formation area 62d in the plan view will be referred to as a photoelectric conversion area 23d. In a case in which these photoelectric conversion areas 23a, 23b, 23c, and 23d do not need to be identified from each other, each thereof will be simply referred to as a photoelectric conversion area 23.

### <Uneven Part>

The wire grid polarizer 60 side of the photoelectric conversion area 23 includes the uneven part 50. In other words, the optical element side of the photoelectric conversion area 23 forms the uneven part 50. The uneven part 50 includes grooves 51. More specifically, the groove 51 is a groove that is concave in the thickness direction of the semiconductor layer 20 from the second face S2. The uneven part 50 includes a plurality of such grooves 51. FIGS. 4 and 6 illustrate an example in which the uneven part 50 has three grooves 51.

In addition, as illustrated in FIG. 4, in the thickness direction (the Z direction), the wire grid polarizer 60 does not overlap the uneven part 50. A part of transmissive-axis light that has passed through the wire grid polarizer 60 is refracted by the uneven part 50 at the time of incident to the photoelectric conversion area 23 and obliquely advances inside the photoelectric conversion area 23. For this reason, an optical path length of the refracted light becomes long, and more light is absorbed in the photoelectric conversion area 23.

The uneven part 50 of the photoelectric conversion area 23a includes a groove 51 extending in a direction forming 90 degrees with the arrangement direction of the groove 63 disposed in the groove formation area 62a (in other words, the extending direction of the groove 63). In addition, the uneven part 50 of the photoelectric conversion area 23b includes a groove 51 extending in a direction forming 90 degrees with the arrangement direction of the groove 63 disposed in the groove formation area 62b (in other words, the extending direction of the groove 63). Furthermore, the uneven part 50 of the photoelectric conversion area 23c includes a groove 51 extending in a direction forming 90 degrees with the arrangement direction of the groove 63 disposed in the groove formation area 62c (in other words, the extending direction of the groove 63). In addition, the uneven part 50 of the photoelectric conversion area 23d includes a groove 51 extending in a direction forming 90 degrees with the arrangement direction of the groove 63 disposed in the groove formation area 62d (in other words, the extending direction of the groove 63)

In this way, in a case in which the wire grid polarizer 60 has a plurality of types of groove formation areas 62 in which arrangement directions of grooves 63 are different from each other, the uneven parts 50 (grooves 51) are disposed such that an extending direction of the grooves 51 of the uneven part 50 constantly forms a predetermined angle (a first angle=90 degrees) with respect to the arrangement direction of the grooves 63 even when the type of groove formation area 62 is different between pixels.

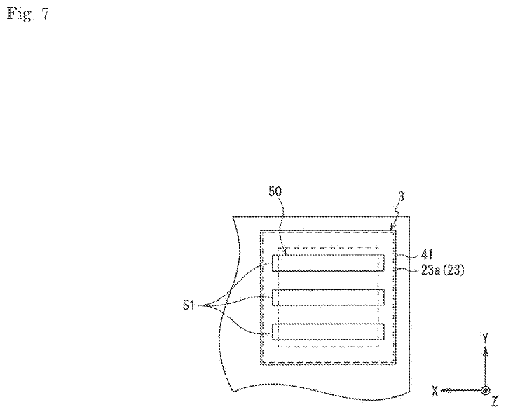

Here, a relation between the extending direction of the grooves 63 and the extending direction of the grooves 51 will be described with reference to a comparative example illustrated in FIG. 7. FIG. 7 illustrates a case in which the grooves 51 included in the uneven part 50 of the photoelectric conversion area 23a extend in a direction forming 0 degrees with the arrangement direction of the grooves 63 disposed in the groove formation area 62a (in other words, a direction forming 90 degrees with the extending direction of the grooves 63). In each of three cases including the case of the photoelectric conversion area 23a illustrated in FIG. 6, the case of the photoelectric conversion area 23a illustrated in FIG. 7, and the case of a photoelectric conversion area in which no uneven part 50 is provided, quantum efficiency representing absorption of light in the semiconductor layer was acquired through a simulation. As a result, the quantum efficiency of the photoelectric conversion area 23a illustrated in FIG. 6 was higher than the quantum efficiency of the photoelectric conversion area 23 in which no uneven part 50 is provided by about 17 percents. In addition, the quantum efficiency of the photoelectric conversion area 23a illustrated in FIG. 7 was higher than the quantum efficiency of the photoelectric conversion area 23 in which no uneven part 50 is provided by about 8 percents.

Through this simulation, it can be understood that the quantum efficiency becomes higher, in other words, the amount of absorption of light increases more in a case in which the uneven part 50 is provided than in a case in which no uneven part 50 is provided. In addition, it can be understood that the quantum efficiency depends on a relative positional relation between the groove 51 of the uneven part 50 and the groove 63 of the wire grid polarizer 60. More specifically, the quantum efficiency of a case in which the groove 51 extends in a direction forming 90 degrees with the arrangement direction of the groove 63 (in other words, a direction forming 0 degrees with the extending direction of the groove 63) is higher than that of a case in which the groove 51 extends in a direction forming 0 degrees with the arrangement direction of the groove 63 (in other words, a direction forming 90 degrees with the extending direction of the groove 63). Thus, in all the pixels 3, by configuring the extending direction of the groove 51 to have a constant angle (first angle) with the arrangement direction of the groove 63 of the wire grid polarizer 60, occurrence of a sensitivity difference between pixels can be inhibited.

In addition, a simulation was performed by changing the angle between the groove 51 and the groove 63, and the quantum efficiency was the highest in a case in which the groove 51 extends in a direction forming 90 degrees with the arrangement direction of the groove 63 (in other words, a direction forming 0 degrees with the extending direction of the groove 63).

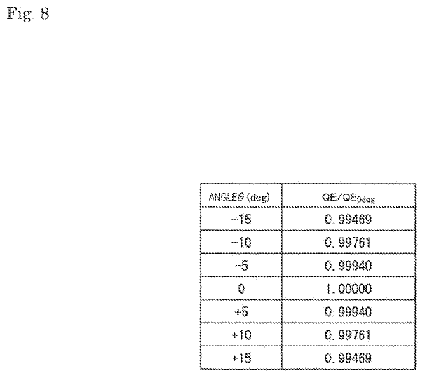

FIG. 8 is a diagram illustrating changes of the quantum efficiency (QE) in a case in which an angle θ (deg) between the extending direction of the groove 63 and the extending direction of the groove 51 is changed. In FIG. 8, quantum efficiency in a case in which quantum efficiency (QE0deg) of a case in which the extending direction of the groove 63 and the extending direction of the groove 51 coincide with each other, in other words, of a case in which the angle θ is 0 degrees (the first angle=90 degrees) is set 1, that is, QE/QE0deg is illustrated. In the case of a range of −10 degrees≤0≤+10 degrees, a reduction rate of the quantum efficiency is within 0.24 percents. In addition, in the case of a range of −5 degrees≤0≤+5 degrees, a reduction rate of the quantum efficiency is within 0.06 percents.

### <Pinning Layer>

On a face (the second face S2) of a side opposite to a face of the multilayer wiring layer 30 side of the semiconductor layer 20, a pinning layer 41 is deposited. More specifically, the pinning layer 41 is deposited in an area including the second face S2 and an inner wall of the isolation groove 24. The pinning layer 41 deposited on the uneven part 50 has a shape along the shape of the uneven part 50. More specifically, the pinning layer 41 deposited on the uneven part 50 has a shape along the shape of the groove 51.

The pinning layer 41 is formed using a high dielectric having a negative fixed charge so that a positive charge (hole) storage region is formed at an interface with the semiconductor layer 20 and the generation of a dark current is suppressed. When the pinning layer 41 is formed to have a negative fixed charge, an electric field is applied to the interface with the semiconductor layer 20 by the negative fixed charge, and thus a positive charge storage region is formed.

The pinning layer 41, for example, is formed using a hafnium oxide (HfO2). In addition, the pinning layer 41 may be formed using zirconium dioxide (ZrO2), tantalum oxide (Ta2O5), or the like.

### <Insulating Film>

On a face of a side opposite to a face of the semiconductor layer 20 side of the pinning layer 41, an insulating film 42A is deposited, for example, using a CVD method or the like. The insulating film 42A, for example, is an oxide silicon film. The insulating film 42A deposited on the uneven part 50 through the pinning layer 41 is deposited such that it is buried in a depression of the uneven part 50, for example, a depression of the groove 51 for planarization.

In addition, the insulating film 42A deposited inside the isolation groove 24 through the pinning layer 41 is deposited to be buried inside the isolation groove 24 for planarization. A part of the insulating film 42A deposited inside the isolation groove 24 through the pinning layer 41 forms an isolation area 42 partitioning photoelectric conversion areas 23 adjacent to each other. The isolation area 42 has a deep trench isolation (DTI) structure in which the insulating film 42A is buried inside the isolation groove 24. Although not illustrated, the isolation area 42 may be disposed to pass through the semiconductor layer 20.

### <Light Shielding Layer>

The light shielding layer 43 is stacked on a face of a side opposite to a face of the pinning layer 41 side of the insulating film 42A. More specifically, the light shielding layer 43 is disposed in an area overlapping the isolation area 42 in the plan view. As a material of the light shielding layer 43, a material shielding light may be used, and, for example, tungsten (W), aluminum (Al), copper (Cu), or the like can be used.

### <Planarization Film>

The planarization film 44 is formed to cover a face of a side opposite to the face of the pinning layer 41 side of the insulating film 42A and the light shielding layer 43. As a material of the planarization film 44, for example, a silicon oxide can be used.

### <<Method of Manufacturing Light Detection Device>>

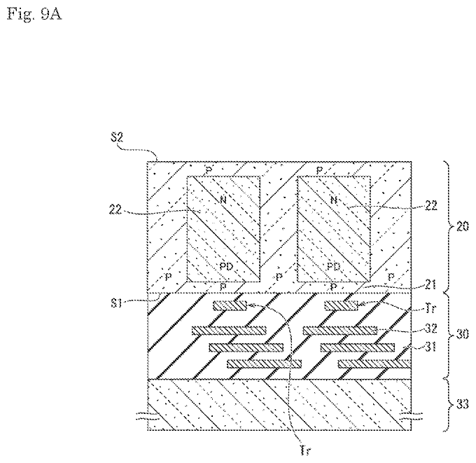

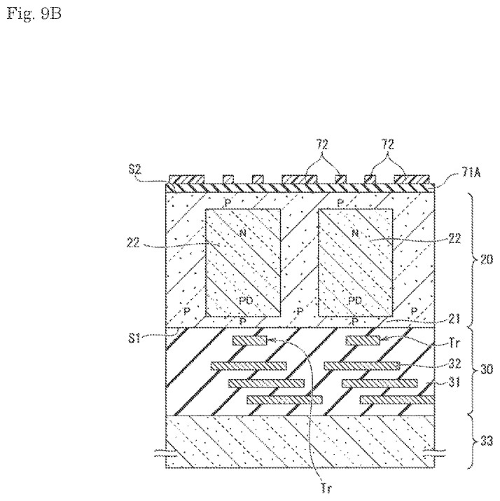

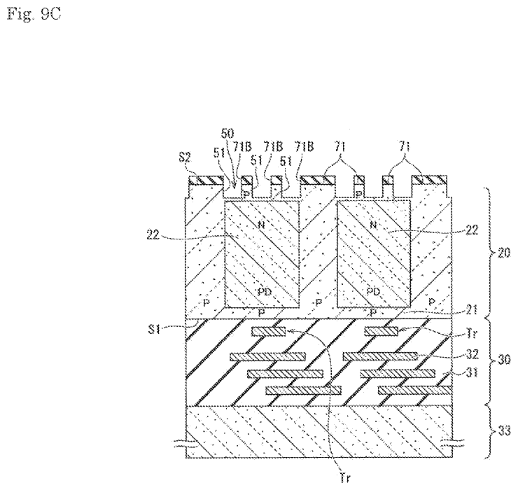

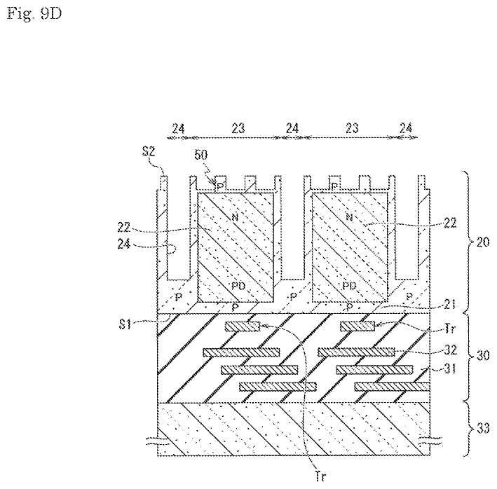

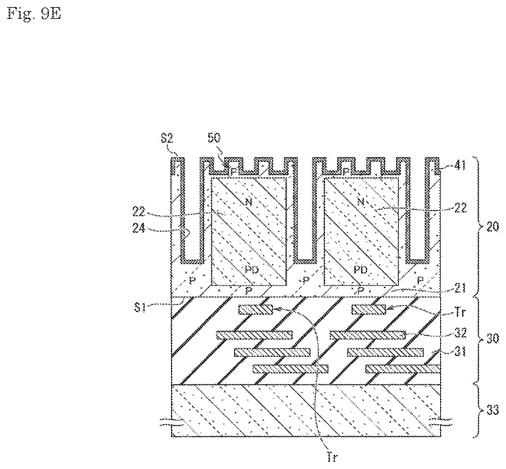

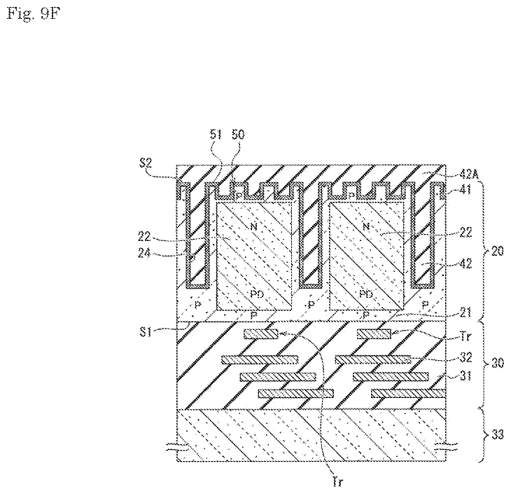

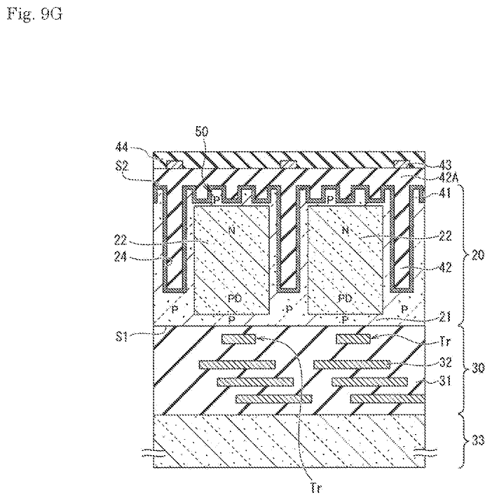

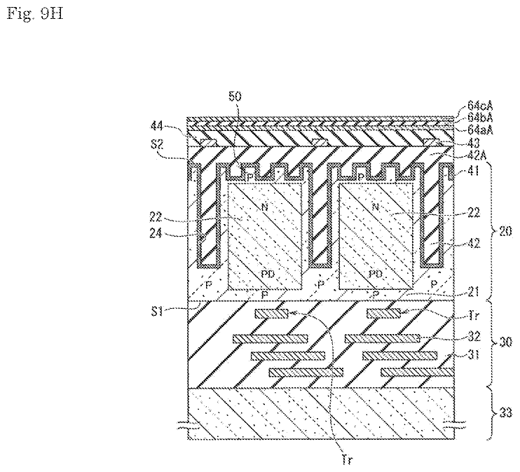

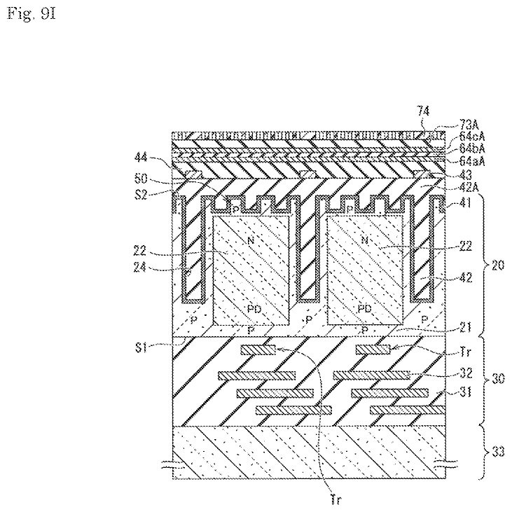

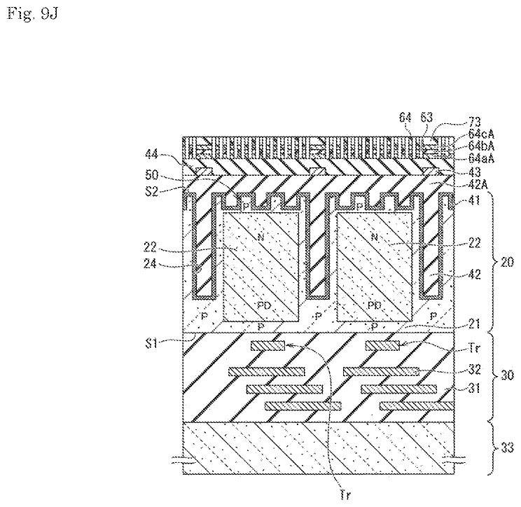

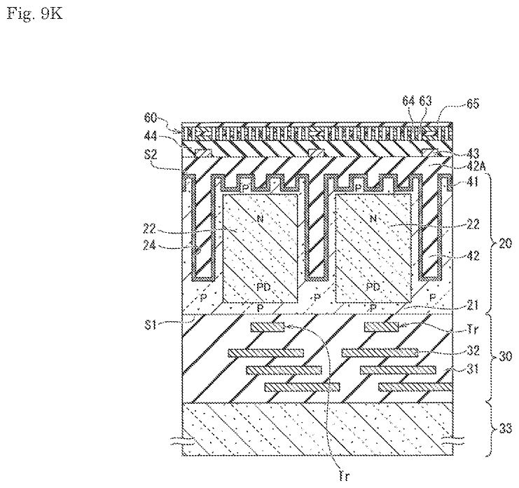

Hereinafter, a method of manufacturing the light detection device 1 will be described with reference to FIGS. 9A to 9K. First, as illustrated in FIG. 9A, a semiconductor layer 20 is prepared. More specifically, a semiconductor region 22 of the n type is formed in the semiconductor layer 20. The semiconductor region 22 of the n type is formed inside a semiconductor region 21 of the p type in the semiconductor layer 20.

Here, although details of the manufacturing method thereof are not illustrated, in an area near the first face S1 side inside the semiconductor layer 20 illustrated in FIG. 9A, transistors, electric charge accumulation area FD, and the like configuring transfer transistor TR, a reading circuit 15, a logic circuit 13, and the like are formed. Then, on the first face S1 side of the semiconductor layer 20, a multilayer wiring layer 30 including an interlayer insulating film 31 and a wiring layer 32 are stacked. In addition, a support substrate 33 is bonded to a face of a side opposite to the face of the semiconductor layer 20 of the multilayer wiring layer 30.

Next, as illustrated in FIG. 9B, on the second face S2 side of the semiconductor layer 20, a mask for forming an uneven part 50 is stacked. More specifically, on the second face S2 side of the semiconductor layer 20, a film 71A for a hard mask is formed. The film 71A, for example, is a silicon oxide film. Then, by using a lithographic technology and an etching technology that are known, a resist pattern 72 is formed on the film 71A. Thereafter, the film 71A is etched using the resist pattern 72 as a mask, and a hard mask 71 illustrated in FIG. 9C is formed.

Then, as illustrated in FIG. 9C, the semiconductor layer 20 exposed from the opening part 71B of the hard mask 71 is etched to form grooves 51. A part in which these grooves 51 are formed is a part of the semiconductor layer 20 that becomes a photoelectric conversion area 23 later. In other words, the grooves 51 are formed in the semiconductor layer 20 of a part corresponding to the photoelectric conversion area 23. In accordance with this process, an uneven part 50 is formed on the second face S2 side of the photoelectric conversion area 23.

Next, as illustrated in FIG. 9D, in a semiconductor region 21 of the p type between the semiconductor regions 22 of the n type adjacent to each other, an isolation groove 24 is formed using a lithographic technology and an etching technology that are known. In accordance with this process, the photoelectric conversion areas 23 are partitioned in an island shape.

Then, as illustrated in FIG. 9E, the pinning layer 41 is deposited on the second face S2 of the semiconductor layer 20, and a heating process is performed. In addition, before this process, the mask for etching has been removed. Thereafter, as illustrated in FIG. 9F, an insulating film 42A is deposited on the pinning layer 41. At this time, the grooves 51 of the uneven part 50 and the inside of the isolation groove 24 are filled with the insulating film 42A. In accordance with this, the isolation area 42 is formed.

Next, as illustrated in FIG. 9G, a light shielding layer 43 is formed on the insulating film 42A, and the planarization film 44 is deposited to cover the light shielding layer 43 and the insulating film 42A. The light shielding layer 43 is not illustrated here. A film formed from a material composing the light shielding layer 43 is formed on the insulating film 42A, and the light shielding layer 43 is formed using a lithographic technology and an etching technology that are known. In addition, although illustration of the planarization film 44 is omitted here, a material composing the planarization film 44 is deposited, and thereafter, the surface of the deposited material is grinded and planarized using a chemical mechanical polishing (CMP) method or the like, whereby the planarization film 44 is formed.

Then, as illustrated in FIG. 9H, a film 64aA formed from a material composing the light reflection layer 64a, a film 64bA formed from a material composing the insulating layer 64b, and a film 64cA formed from a material composing the light absorption layer 64c are stacked on the planarization film 44 in that order.

Next, on the film 64cA, a mask for forming the band-shaped conductor 64 of the wire grid polarizer 60 is formed. More specifically, as illustrated in FIG. 9I, on the film 64cA, a film 73A for a hard mask is formed, and a resist pattern 74 is formed thereon using a lithographic technology and an etching technology that are known. Then, the film 73A is etched using the resist pattern 74 as a mask, and a hard mask 73 illustrated in FIG. 9J is formed. The film 73A, for example, is a silicon oxide film.

Then, as illustrated in FIG. 9J, grooves 63 are formed by etching the film 64aA, the film 64bA, and the film 64cA using the hard mask 73, and the light reflection layer 64a, the insulating layer 64b, and the light absorption layer 64c are cut out for each band-shaped conductor 64. Thereafter, although not illustrated, the hard mask 73 is removed, and a protection layer 64d is formed to cover the light reflection layer 64a, the insulating layer 64b, and the light absorption layer 64c that have been cut out. In accordance with this, the formation of the band-shaped conductor 64 is completed. Thereafter, as illustrated in FIG. 9K, a planarization film 65 is formed on the band-shaped conductor 64. In accordance with this, the formation of the wire grid polarizer 60 is completed.

Then, after the wire grid polarizer 60 is formed, although not illustrated, a micro-lens 45 is formed on the wire grid polarizer 60, and the light detection device 1 illustrated in FIG. 4 is almost finished. The light detection device 1 is formed in each of a plurality of chip formation area partitioned using a scriber line (dicing line) in the semiconductor substrate. Then, by individually dividing these plurality of chip formation areas along the scriber line, the semiconductor chip 2 in which the light detection device 1 is built is formed.

### <<Main Effect of First Embodiment>>

Main effects of the first embodiment will be described. As described above with reference to FIG. 5C, the wire grid polarizer 60 transmits only polarized light Lb out of the polarized light La (extinction-axis light) and the polarized light Lb (transmissive-axis light). For this reason, in a case in which the light detection device 1 includes the wire grid polarizer 60, only transmissive-axis light out of light incident in the light detection device 1 is supplied to the photoelectric conversion area 23. In other words, light incident in the photoelectric conversion area 23 is limited to light of one polarization direction. For this reason, compared to a light detection device 1 not having the wire grid polarizer 60, the light detection device 1 having the wire grid polarizer 60 has a decreased light quantity, and thus lowering of sensitivity is unavoidable.

In the light detection device 1 according to the first embodiment of the present technology, since the second face S2 side of the photoelectric conversion area 23 has the uneven parts 50, a part of transmissive-axis light that has passed through the wire grid polarizer 60 is refracted by the uneven part 50 at the time of incident to the photoelectric conversion area 23 and obliquely advances inside the photoelectric conversion area 23. For this reason, an optical path length of the refracted light becomes long, and more light is absorbed in the photoelectric conversion area 23. In accordance with this, even in a case in which the wire grid polarizer 60 is included, the light detection device 1 can efficiently absorb transmissive-axis light, and thus the lowering of the sensitivity of the light detection device 1 can be supplemented.

In addition, in a case in which the wire grid polarizer 60 includes a plurality of types of groove formation areas 62 in which the arrangement directions of grooves 63 are different from each other, the uneven parts 50 (grooves 51) are disposed such that an extending direction of the grooves 51 of the uneven part 50 constantly forms a predetermined angle (a first angle) with respect to the arrangement direction of the grooves 63 even when the type of groove formation area 62 is different between pixels, and thus occurrence of a sensitivity difference between pixels having different types of groove formation areas 62 can be inhibited.

In addition, in the light detection device 1 according to the first embodiment of the present technology, the uneven part 50 extends in a direction forming 90 degrees with the arrangement direction of the grooves 63, that is, the extending direction of the grooves 63, and thus the quantum efficiency becomes the highest. In accordance with this, a time in which the photoelectric conversion area 23 accumulates signal electric charge can be shortened, and thus it is effective in a case in which the light detection device 1 is desired to be operated at a high frame rate or the like.

In addition, the arrangement pitch of the groove 51, for example, may be determined in accordance with the wavelength of light incident in the light detection device 1. Furthermore, the number of grooves 51 included in the uneven part 50 may be determined in accordance with a pixel region.

In addition, although the band-shaped conductor 64 includes the light reflection layer 64a, the insulating layer 64b, the light absorption layer 64c, and the protection layer 64d, it may include at least the light reflection layer 64a. Furthermore, although the wire grid polarizer 60 has an air gap structure, it may have any other structure. For example, the insulating film may be buried in the groove 63.

In addition, in the manufacturing method described above, although the isolation groove 24 is formed after the grooves 51 are formed, the grooves 51 may be formed after the isolation groove 24 is formed.

Furthermore, in a case in which the photoelectric conversion area 23 is in the plan view, it is preferable unevenness (in this embodiment, the groove 51) of the uneven part 50 be present at the center part out of the center part of the photoelectric conversion area 23 and a part near the end part (a part near the isolation groove 24).

### Modified Example 1 of First Embodiment

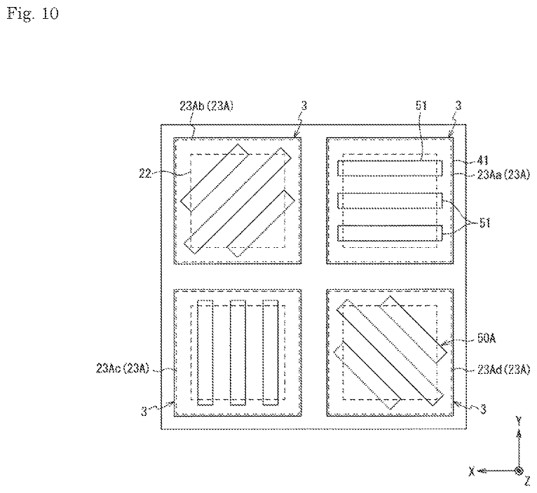

Modified Example 1 of the first embodiment of the present technology illustrated in FIG. 10 will be described below. A light detection device 1 according to this Modified Example 1 of the first embodiment is different from the light detection device 1 according to the first embodiment described above in that a photoelectric conversion area 23A is included in place of the photoelectric conversion area 23, an uneven part 50A is included in place of the uneven part 50, and the groove 51 of the uneven part 50A extends in a direction forming 0 degrees with the arrangement direction of the groove 63 disposed in the groove formation area 62 (that is, a direction forming 90 degrees with the extending direction of the groove 63), and the other configurations of the light detection device 1 are basically similar to those of the light detection device 1 according to the first embodiment described above. The same reference signs will be assigned to constituent elements that have already been described, and description thereof will be omitted.

### <Photoelectric Conversion Area>

The light detection device 1 according to Modified Example 1 of the first embodiment includes the photoelectric conversion area 23A. A relation between the photoelectric conversion area 23A and the wire grid polarizer 60 is similar to that of the first embodiment, and the photoelectric conversion areas 23, 23a, 23b, 23c, and 23d illustrated in FIG. 5A may be rephrased as photoelectric conversion areas 23A, 23Aa, 23Ab, 23Ac, and 23Ad.

### <Uneven Part>

The wire grid polarizer 60 side of the photoelectric conversion area 23A includes an uneven part 50A. In other words, the optical element side of the photoelectric conversion area 23A forms the uneven part 50A. The uneven part 50A includes grooves 51. FIG. 10 illustrates an example in which the uneven part 50 includes three grooves 51.

The uneven part 50A of the photoelectric conversion area 23Aa includes a groove 51 extending in a direction forming 0 degrees with the arrangement direction of the groove 63 disposed in the groove formation area 62a (in other words, a direction forming 90 degrees with the extending direction of the groove 63). In addition, the uneven part 50A of the photoelectric conversion area 23Ab includes a groove 51 extending in a direction forming 0 degrees with the arrangement direction of the groove 63 disposed in the groove formation area 62b (in other words, a direction forming 90 degrees with the extending direction of the groove 63). Furthermore, the uneven part 50A of the photoelectric conversion area 23Ac includes a groove 51 extending in a direction forming 0 degrees with the arrangement direction of the groove 63 disposed in the groove formation area 62c (in other words, a direction forming 90 degrees with the extending direction of the groove 63). In addition, the uneven part 50A of the photoelectric conversion area 23Ad includes a groove 51 extending in a direction forming 0 degrees with the arrangement direction of the groove 63 disposed in the groove formation area 62d (in other words, a direction forming 90 degrees with the extending direction of the groove 63).

In this way, in a case in which the wire grid polarizer 60 has a plurality of types of groove formation areas 62 in which arrangement directions of grooves 63 are different from each other, the uneven parts 50A (grooves 51) are disposed such that an extending direction of the grooves 51 of the uneven part 50A constantly forms a predetermined angle (a first angle=0 degrees) with the arrangement direction of the grooves 63 even when the type of groove formation area 62 is different between pixels.

In addition, as described above in the first embodiment, as a result of a simulation, the quantum efficiency of the photoelectric conversion area 23A of a case in which the groove 51 of the uneven part 50A extends in a direction forming 0 degrees with the arrangement direction of the groove 63 (in other words, a direction forming 90 degrees with the extending direction of the groove 63) is higher than the quantum efficiency of the photoelectric conversion area 23 that does not have the uneven part 50 by about 8 percents.

In addition, the quantum efficiency of the photoelectric conversion area 23A is lower than the quantum efficiency of the photoelectric conversion area 23. In a simple comparison of the quantum efficiency, this represents that the photoelectric conversion area 23 can absorb transmissive-axis light more efficiently than the photoelectric conversion area 23A. The reason for this is that the amount of light that is refracted by the groove 51 and obliquely advances is larger in the photoelectric conversion area 23 than in the photoelectric conversion area 23A.

Here, in a case in which the polarization plane of transmissive-axis light is different between pixels 3 adjacent to each other, when a crosstalk occurs, light having different polarization planes are mixed. For this reason, there are cases in which the crosstalk has an influence on the extinction ratio. It is assumed that the amount of light that is refracted and obliquely advances is smaller in the photoelectric conversion area 23A than in the photoelectric conversion area 23, and thus a crosstalk for an adjacent pixel is assumed to be smaller therein than in the photoelectric conversion area 23. In other words, in the photoelectric conversion area 23A, the extinction ratio is higher than in the photoelectric conversion area 23.

### <<Main Effect of Modified Example 1 of First Embodiment>>

Also in the case of the light detection device 1 according to this Modified Example 1 of the first embodiment, effects similar to those of the light detection device 1 according to the first embodiment described above can be acquired.

In addition, the photoelectric conversion area 23A of the light detection device 1 according to Modified Example 1 of the first embodiment has a high extinction ratio than the photoelectric conversion area 23, and thus in a case in which the extinction ratio is more significant out of the quantum efficiency and the extinction ratio, the configuration of the photoelectric conversion area 23A may be applied to the light detection device 1.

### Modified Example 2 of First Embodiment

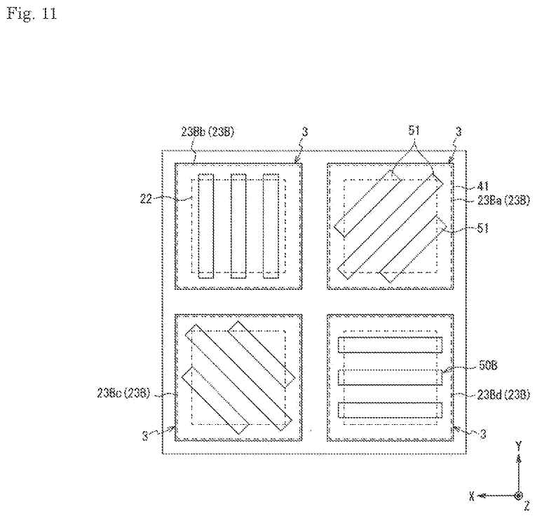

Modified Example 2 of the first embodiment of the present technology illustrated in FIG. 11 will be described below. A light detection device 1 according to Modified Example 2 of this first embodiment is different from the light detection device 1 according to the first embodiment described above in that the groove 51 extends in a direction forming 45 degrees with the arrangement direction of the groove 63 disposed in the groove formation area 62 (that is, a direction forming 45 degrees with the extending direction of the groove 63), and the other configurations of the light detection device 1 are basically similar to those of the light detection device 1 according to the first embodiment described above. The same reference signs will be assigned to constituent elements that have already been described, and description thereof will be omitted.

### <Photoelectric Conversion Area>

The light detection device 1 according to Modified Example 2 of the first embodiment includes a photoelectric conversion area 23B. A relation between the photoelectric conversion area 23B and the wire grid polarizer 60 is similar to that of the first embodiment, and the photoelectric conversion areas 23, 23a, 23b, 23c, and 23d illustrated in FIG. 5A may be rephrased as photoelectric conversion areas 23B, 23Ba, 23Bb, 23Bc, and 23Bd.

### <Uneven Part>

The wire grid polarizer 60 side of the photoelectric conversion area 23B includes an uneven part 50B. In other words, the optical element side of the photoelectric conversion area 23B forms the uneven part 50B. The uneven part 50B includes grooves 51. FIG. 11 illustrates an example in which the uneven part 50 includes three grooves 51.

The uneven part 50B of the photoelectric conversion area 23Ba includes a groove 51 extending in a direction forming 45 degrees with the arrangement direction of the groove 63 disposed in the groove formation area 62a (in other words, a direction forming 45 degrees with the extending direction of the groove 63). In addition, the uneven part 50B of the photoelectric conversion area 23Bb includes a groove 51 extending in a direction forming 45 degrees with the arrangement direction of the groove 63 disposed in the groove formation area 62b (in other words, a direction forming 45 degrees with the extending direction of the groove 63). Furthermore, the uneven part 50B of the photoelectric conversion area 23Bc includes a groove 51 extending in a direction forming 45 degrees with the arrangement direction of the groove 63 disposed in the groove formation area 62c (in other words, a direction forming 45 degrees with the extending direction of the groove 63). In addition, the uneven part 50B of the photoelectric conversion area 23Bd includes a groove 51 extending in a direction forming 45 degrees with the arrangement direction of the groove 63 disposed in the groove formation area 62d (in other words, a direction forming 45 degrees with the extending direction of the groove 63).

In this way, in a case in which the wire grid polarizer 60 has a plurality of types of groove formation areas 62 in which arrangement directions of grooves 63 are different from each other, the uneven parts 50B (grooves 51) are disposed such that an extending direction of the grooves 51 of the uneven part 50B constantly forms a predetermined angle (a first angle=45 degrees) with the arrangement direction of the grooves 63 even when the type of groove formation area 62 is different between pixels.

### <<Main Effect of Modified Example 2 of First Embodiment>>

Also in the case of the light detection device 1 according to this Modified Example 2 of the first embodiment, effects similar to those of the light detection device 1 according to the first embodiment described above can be acquired.

In addition, the photoelectric conversion area 23B of the light detection device 1 according to Modified Example 2 of the first embodiment has a value of the quantum efficiency between the quantum efficiency of the photoelectric conversion area 23 according to the first embodiment and the quantum efficiency of the photoelectric conversion area 23A according to Modified Example 1 of the first embodiment. In addition, the photoelectric conversion area 23B has a value of the extinction ratio between the extinction ratio of the photoelectric conversion area 23 according to the first embodiment and the extinction ratio of the photoelectric conversion area 23A according to Modified Example 1 of the first embodiment. For this reason, in a case in which a balance between the quantum efficiency and the extinction ratio is significant, the configuration of the photoelectric conversion area 23B may be applied to the light detection device 1.

In addition, the first angle is not limited to 45 degrees but may be 135 degrees. In such a case, the groove 51 of the photoelectric conversion area 23Ba extends in a direction forming 135 degrees with the arrangement direction of the groove 63 disposed in the groove formation area 62a (in other words, a direction forming 45 degrees with the extending direction of the groove 63). In addition, the groove 51 of the photoelectric conversion area 23Bb extends in a direction forming 135 degrees with the arrangement direction of the groove 63 disposed in the groove formation area 62b (in other words, a direction forming 45 degrees with the extending direction of the groove 63). Furthermore, the groove 51 of the photoelectric conversion area 23Bc extends in a direction forming 135 degrees with the arrangement direction of the groove 63 disposed in the groove formation area 62c (in other words, a direction forming 45 degrees with the extending direction of the groove 63). In addition, the groove 51 of the photoelectric conversion area 23Bd extends in a direction forming 135 degrees with the arrangement direction of the groove 63 disposed in the groove formation area 62d (in other words, a direction forming 45 degrees with the extending direction of the groove 63). Also in a case in which the first angle is 135 degrees, effects similar to a case in which the first angle is 45 degrees can be acquired.

### Modified Example 3 of First Embodiment

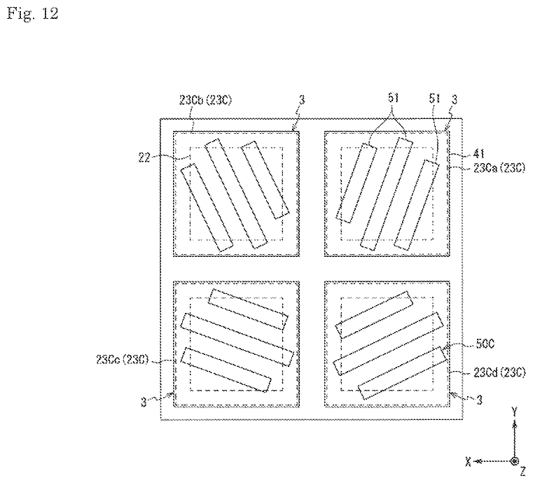

Modified Example 3 of the first embodiment of the present technology illustrated in FIG. 12 will be described below. A light detection device 1 according to this Modified Example 3 of the first embodiment is different from the light detection device 1 according to the first embodiment described above in that the groove 51 extends in a direction forming an angle other than the angles described above with the arrangement direction of the groove 63 disposed in the groove formation area 62, and the other configurations of the light detection device 1 are basically similar to those of the light detection device 1 according to the first embodiment described above. The same reference signs will be assigned to constituent elements that have already been described, and description thereof will be omitted.

### <Photoelectric Conversion Area>

The light detection device 1 according to Modified Example 3 of the first embodiment includes a photoelectric conversion area 23C. A relation between the photoelectric conversion area 23C and the wire grid polarizer 60 is similar to that of the first embodiment, and the photoelectric conversion areas 23, 23a, 23b, 23c, and 23d illustrated in FIG. 5A may be rephrased as photoelectric conversion areas 23C, 23Ca, 23Cb, 23Cc, and 23Cd.

### <Uneven Part>

The wire grid polarizer 60 side of the photoelectric conversion area 23C includes an uneven part 50C. In other words, the optical element side of the photoelectric conversion area 23C forms the uneven part 50C. The uneven part 50C includes grooves 51. FIG. 12 illustrates an example in which the uneven part 50 includes three grooves 51. In this Modified Example 3 of the first embodiment, the first angle has an arbitrary angle other than 90 degrees, 0 degrees, and 45 degrees described above. Here, although a case in which the first angle=70 degrees as an arbitrary angle will be described, however, the first angle is not limited to this angle.

The uneven part 50C of the photoelectric conversion area 23Ca includes a groove 51 extending in a direction forming 70 degrees with the arrangement direction of the groove 63 disposed in the groove formation area 62a (in other words, a direction forming 20 degrees with the extending direction of the groove 63). In addition, the uneven part 50C of the photoelectric conversion area 23Cb includes a groove 51 extending in a direction forming 70 degrees with the arrangement direction of the groove 63 disposed in the groove formation area 62b (in other words, a direction forming 20 degrees with the extending direction of the groove 63). Furthermore, the uneven part 50C of the photoelectric conversion area 23Cc includes a groove 51 extending in a direction forming 70 degrees with the arrangement direction of the groove 63 disposed in the groove formation area 62c (in other words, a direction forming 20 degrees with the extending direction of the groove 63). In addition, the uneven part 50C of the photoelectric conversion area 23Cd includes a groove 51 extending in a direction forming 70 degrees with the arrangement direction of the groove 63 disposed in the groove formation area 62d (in other words, a direction forming 20 degrees with the extending direction of the groove 63).

In this way, in a case in which the wire grid polarizer 60 has a plurality of types of groove formation areas 62 in which arrangement directions of grooves 63 are different from each other, the uneven parts 50C (grooves 51) are disposed such that an extending direction of the grooves 51 of the uneven part 50C constantly forms a predetermined angle (a first angle) with the arrangement direction of the grooves 63 even when the type of groove formation area 62 is different between pixels.

### <<Main Effect of Modified Example 3 of First Embodiment>>

Also in the case of the light detection device 1 according to this Modified Example 3 of the first embodiment, effects similar to those of the light detection device 1 according to the first embodiment described above can be acquired.

In addition, in this Modified Example 3 of the first embodiment, the first angle is configured as an arbitrary angle, and thus the first angle that is optimal in accordance with the design of the light detection device 1 can be selected.

### Modified Example 4 of First Embodiment

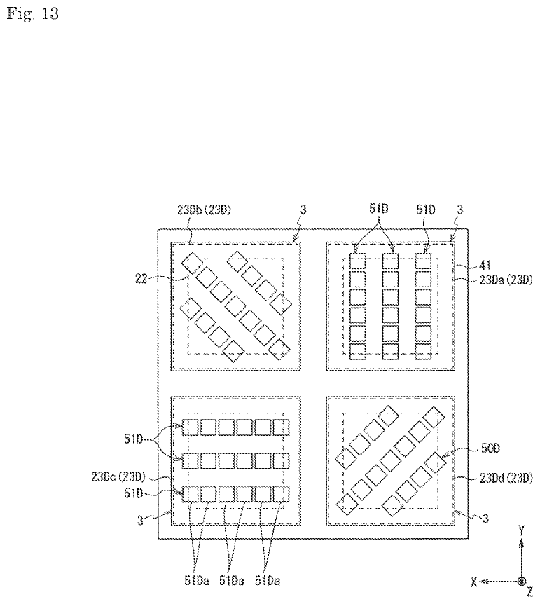

Modified Example 4 of the first embodiment of the present technology illustrated in FIG. 13 will be described below. A light detection device 1 according to this Modified Example 4 of the first embodiment is different from the light detection device 1 according to the first embodiment described above in that a concave part group 51D is included in place of the groove 51, and the other configurations of the light detection device 1 are basically similar to those of the light detection device 1 according to the first embodiment described above. The same reference signs will be assigned to constituent elements that have already been described, and description thereof will be omitted.

### <Photoelectric Conversion Area>

The light detection device 1 according to Modified Example 4 of the first embodiment includes a photoelectric conversion area 23D. A relation between the photoelectric conversion area 23D and the wire grid polarizer 60 is similar to that of the first embodiment, and the photoelectric conversion areas 23, 23a, 23b, 23c, and 23d illustrated in FIG. 5A may be rephrased as photoelectric conversion areas 23D, 23Da, 23Db, 23Dc, and 23Dd.

### <Uneven Part>

The wire grid polarizer 60 side of the photoelectric conversion area 23D includes an uneven part 50D. In other words, the optical element side of the photoelectric conversion area 23D forms the uneven part 50D. The uneven part 50D includes concave part groups 51D. FIG. 13 illustrates an example in which the uneven part 50D includes three concave part groups 51D. The concave part group 51D includes a plurality of concave parts (first concave parts) 51Da aligned in one column. The arrangement direction of the plurality of concave parts 51Da corresponds to the extending direction of the concave part group 51D.

The uneven part 50D of the photoelectric conversion area 23Da includes a concave part group 51D extending in a direction forming 90 degrees with the arrangement direction of a groove 63 disposed in the groove formation area 62a (in other words, the extending direction of the groove 63). In addition, the uneven part 50D of the photoelectric conversion area 23Db includes a concave part group 51D extending in a direction forming 90 degrees with the arrangement direction of a groove 63 disposed in the groove formation area 62b (in other words, the extending direction of the groove 63). Furthermore, the uneven part 50D of the photoelectric conversion area 23Dc includes a concave part group 51D extending in a direction forming 90 degrees with the arrangement direction of a groove 63 disposed in the groove formation area 62c (in other words, the extending direction of the groove 63). In addition, the uneven part 50D of the photoelectric conversion area 23Dd includes a concave part group 51D extending in a direction forming 90 degrees with the arrangement direction of a groove 63 disposed in the groove formation area 62d (in other words, the extending direction of the groove 63).

In this way, in a case in which the wire grid polarizer 60 has a plurality of types of groove formation areas 62 in which arrangement directions of grooves 63 are different from each other, the uneven parts 50D (the concave part group 51D) are disposed such that an extending direction of the concave part group 51D of the uneven part 50D constantly forms a predetermined angle (a first angle=90 degrees) with the arrangement direction of the grooves 63 even when the type of groove formation area 62 is different between pixels.

### <<Main Effect of Modified Example 4 of First Embodiment>>

Also in the case of the light detection device 1 according to this Modified Example 4 of the first embodiment, effects similar to those of the light detection device 1 according to the first embodiment described above can be acquired.

In addition, in the example illustrated in FIG. 13, although each concave part 51Da has a square shape, the shape is not limited thereto, and a rectangular shape or a circular shape may be used. In addition, in the example illustrated in FIG. 13, although the plurality of concave parts 51Da have the same shape, the configuration is not limited thereto, and the plurality of concave parts 51Da may have different shapes.

### Second Embodiment

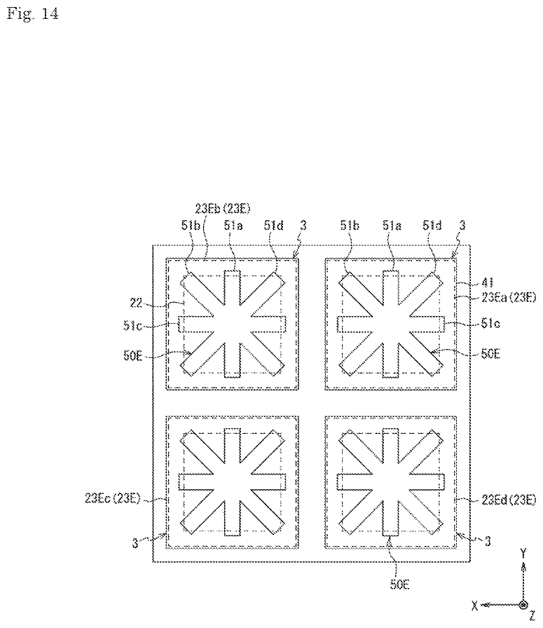

A second embodiment of the present technology illustrated in FIG. 14 will be described below. A light detection device 1 according to this second embodiment is different from the light detection device 1 according to the first embodiment described above in that a photoelectric conversion area 23E is included in place of the photoelectric conversion area 23, photoelectric conversion areas 23Ea, 23Eb, 23Ec, and 23Ed have uneven parts 50E of the same shape, and the uneven part 50E has grooves 51 extending in different directions, and the other configurations of the light detection device 1 are basically similar to those of the light detection device 1 according to the first embodiment described above. The same reference signs will be assigned to constituent elements that have already been described, and description thereof will be omitted.

### <Photoelectric Conversion Area>

The light detection device 1 according to the second embodiment includes the photoelectric conversion area 23E. A relation between the photoelectric conversion area 23E and the wire grid polarizer 60 is similar to that of the first embodiment, and the photoelectric conversion areas 23, 23a, 23b, 23c, and 23d illustrated in FIG. 5A may be rephrased as photoelectric conversion areas 23E, 23Ea, 23Eb, 23Ec, 23Ed. As illustrated in FIG. 14, all the photoelectric conversion areas 23Ea, 23Eb, 23Ec, and 23Ed have the uneven parts 50E of the same shape.

### <Uneven Part>

A wire grid polarizer 60 side of the photoelectric conversion area 23E includes an uneven part 50E. In other words, an optical element side of the photoelectric conversion area 23E forms the uneven part 50E. The uneven part 50E includes grooves 51 extending in different directions.

More specifically, the uneven part 50E of the photoelectric conversion area 23Ea includes all of a groove 51a extending in a direction forming 90 degrees with the arrangement direction of the groove 63 disposed in the groove formation area 62a (in other words, the extending direction of the groove 63), a groove 51b extending in a direction forming 90 degrees with the arrangement direction of the groove 63 disposed in the groove formation area 62b (in other words, the extending direction of the groove 63), a groove 51c extending in a direction forming 90 degrees with the arrangement direction of the groove 63 disposed in the groove formation area 62c (in other words, the extending direction of the groove 63), and a groove 51d extending in a direction forming 90 degrees with the arrangement direction of the groove 63 disposed in the groove formation area 62d (in other words, the extending direction of the groove 63). Similarly, each of the uneven part 50E of the photoelectric conversion area 23Eb, the uneven part 50E of the photoelectric conversion area 23Ec, and the uneven part 50E of the photoelectric conversion area 23Ed includes grooves 51a to 51d. In this way, the uneven part 50E of the photoelectric conversion area 23Ea, the uneven part 50E of the photoelectric conversion area 23Eb, the uneven part 50E of the photoelectric conversion area 23Ec, and the uneven part 50E of the photoelectric conversion area 23Ed have the same shape. In addition, in a case in which these grooves 51a, 51b, 51c, and 51d do not need to be identified from each other, each thereof will be simply referred to as a groove 51.

In this way, since each uneven part 50E includes the groove 51a to the groove 51d extending in different directions, when the uneven part 50E overlaps a certain groove formation area among the groove formation areas 62a, 62b, 62c, and 62d, occurrence of a sensitivity difference between pixels having different types of groove formation areas 62 can be inhibited by the uneven part 50E of the same shape (one type).

### <<Main Effect of Second Embodiment>>

Also in the case of the light detection device 1 according to this second embodiment, effects similar to those of the light detection device 1 according to the first embodiment described above can be acquired.

In addition, the light detection device 1 according to this second embodiment can employ the uneven parts 50E that are common in all the pixels 3, and thus mask data can be easily generated. In addition, manufacturing processes such as etching and the like can be uniformly performed in all the pixels 3.

### Modified Example 1 of Second Embodiment

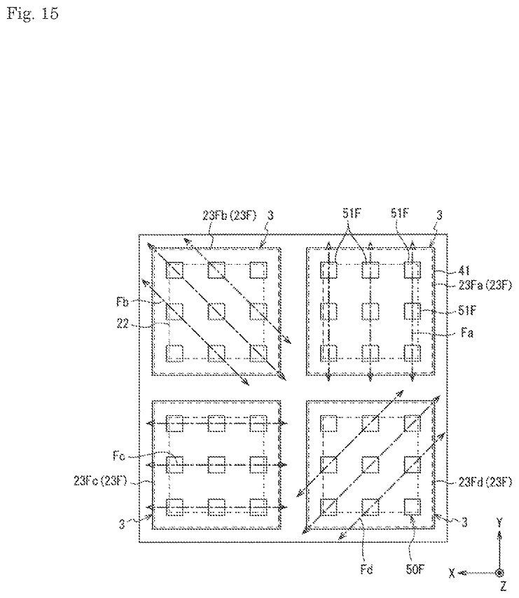

Modified Example 1 of the second embodiment of the present technology illustrated in FIG. 15 will be described below. A light detection device 1 according to this Modified Example 1 of the second embodiment is different from the light detection device 1 according to the second embodiment described above in that an uneven part 50F has concave parts 51F arranged in a matrix pattern, and the other configurations of the light detection device 1 are basically similar to those of the light detection device 1 according to the second embodiment described above. The same reference signs will be assigned to constituent elements that have already been described, and description thereof will be omitted.

### <Photoelectric Conversion Area>

The light detection device 1 according to Modified Example 1 of the second embodiment includes a photoelectric conversion area 23F. A relation between the photoelectric conversion area 23F and the wire grid polarizer 60 is similar to that of the first embodiment, and the photoelectric conversion areas 23, 23a, 23b, 23c, and 23d illustrated in FIG. 5A may be rephrased as photoelectric conversion areas 23F, 23Fa, 23Fb, 23Fc, and 23Fd. In addition, as illustrated in FIG. 15, all the photoelectric conversion areas 23Fa, 23Fb, 23Fc, and 23Fd has the uneven parts 50F of the same shape.

### <Uneven Part>

The wire grid polarizer 60 side of the photoelectric conversion area 23F includes an uneven part 50F. In other words, the optical element side of the photoelectric conversion area 23F forms the uneven part 50F. The uneven part 50F of the photoelectric conversion area 23Fa has a plurality of concave parts (second concave parts) 51F arranged in a matrix pattern in the X direction and the Y direction. The plurality of concave parts 51F, for example, are arranged in a matrix pattern at equal spaces in the X direction and the Y direction. Also each of the uneven part 50F of the photoelectric conversion area 23Fb, similarly, the uneven part 50F of the photoelectric conversion area 23Fc, and the uneven part 50F of the photoelectric conversion area 23Fd includes a plurality of concave parts 51F arranged in a matrix pattern in the X direction and the Y direction. In this way, the uneven part 50F of the photoelectric conversion area 23Fa, the uneven part 50F of the photoelectric conversion area 23Fb, the uneven part 50F of the photoelectric conversion area 23Fc, and the uneven part 50F of the photoelectric conversion area 23Fd have the same shape. Although FIG. 15 illustrates an example in which the concave parts 51F are arranged in three rows and three columns, the arrangement is not limited thereto. In addition, although FIG. 15 illustrates an example in which the concave part 51F has a square shape, the configuration is not limited thereto.

The concave parts 51F arranged in a matrix pattern can be regarded to be arranged along arrows Fa, Fb, Fc, and Fd.

More specifically, the arrow Fa is along a direction forming 90 degrees with the arrangement direction of the groove 63 disposed in the groove formation area 62a (in other words, the extending direction of the groove 63), and the concave part 51F can be regarded to be arranged along the arrow Fa. In addition, the arrow Fb is along a direction forming 90 degrees with the arrangement direction of the groove 63 disposed in the groove formation area 62b (in other words, the extending direction of the groove 63), and the concave part 51F can be regarded to be arranged along the arrow Fb. The arrow Fc is along a direction forming 90 degrees with the arrangement direction of the groove 63 disposed in the groove formation area 62c (in other words, the extending direction of the groove 63), and the concave part 51F can be regarded to be arranged along the arrow Fc. In addition, the arrow Fd is along a direction forming 90 degrees with the arrangement direction of the groove 63 disposed in the groove formation area 62d (in other words, the extending direction of the groove 63), and the concave part 51F can be regarded to be arranged along the arrow Fd.

In this way, since the plurality of concave parts 51F can be regarded to extend in a plurality of directions, when the uneven part 50F overlap a certain groove formation area among the groove formation areas 62a, 62b, 62c, and 62d, occurrence of a sensitivity difference between pixels having different types of groove formation areas 62 can be inhibited by the uneven part 50F of the same shape (one type).

### <<Main Effect of Modified Example 1 of Second Embodiment>>

Also in the case of the light detection device 1 according to this Modified Example 1 of the second embodiment, effects similar to those of the light detection device 1 according to the second embodiment described above can be acquired.

### Modified Example 2 of Second Embodiment

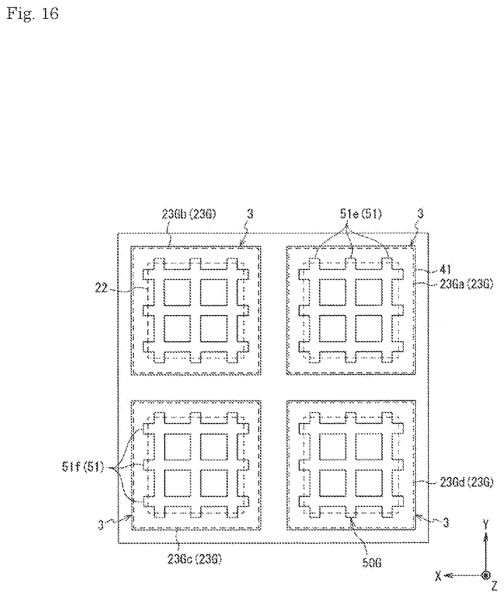

Modified Example 2 of the second embodiment of the present technology illustrated in FIG. 16 will be described below. A light detection device 1 according to this Modified Example 2 of the second embodiment is different from the light detection device 1 according to the second embodiment described above in that an uneven part 50G has two types of grooves 51 extending in different directions, and the other configurations of the light detection device 1 are basically similar to those of the light detection device 1 according to the second embodiment described above. The same reference signs will be assigned to constituent elements that have already been described, and description thereof will be omitted.

### <Photoelectric Conversion Area>

The light detection device 1 according to Modified Example 2 of the second embodiment includes a photoelectric conversion area 23G. A relation between the photoelectric conversion area 23G and the wire grid polarizer 60 is similar to that of the first embodiment, and the photoelectric conversion areas 23, 23a, 23b, 23c, and 23d illustrated in FIG. 5A may be rephrased as photoelectric conversion areas 23G, 23Ga, 23Gb, 23Gc, and 23Gd. In addition, as illustrated in FIG. 16, all the photoelectric conversion areas 23Ga, 23Gb, 23Gc, and 23Gd have the uneven parts 50G of the same shape.

### <Uneven Part>

The wire grid polarizer 60 side of the photoelectric conversion area 23G includes an uneven part 50G. In other words, the optical element side of the photoelectric conversion area 23G forms the uneven part 50G. The uneven part 50G includes grooves 51 extending in different directions. More specifically, the uneven part 50G has a plurality of grooves 51e extending in the Y direction and has a plurality of grooves 51f extending in the X direction. Each of the uneven part 50G of the photoelectric conversion area 23Ga, the uneven part 50G of the photoelectric conversion area 23Gb, uneven part 50G of the photoelectric conversion area 23Gc, and uneven part 50G of the photoelectric conversion area 23Gd has a plurality of grooves 51e and a plurality of grooves 51f.

The groove 51e extends in a direction forming 90 degrees with the arrangement direction of the groove 63 disposed in the groove formation area 62a (in other words, the extending direction of the groove 63). The groove 51f extends in a direction forming 90 degrees with the arrangement direction of the groove 63 disposed in the groove formation area 62c (in other words, the extending direction of the groove 63). In addition, in a case in which these grooves 51e and 51f do not need to be identified from each other, each thereof will be simply referred to as a groove 51.

In this way, each of the uneven parts 50G includes two types of grooves 51e and 51f extending in different directions. In this way, each of the uneven parts 50G may include at least two types of grooves 51 extending in different directions.

### <<Main Effect of Modified Example 2 of Second Embodiment>>

Also in the case of the light detection device 1 according to this Modified Example 2 of the second embodiment, effects similar to those of the light detection device 1 according to the second embodiment described above can be acquired.

### Modified Example 3 of Second Embodiment

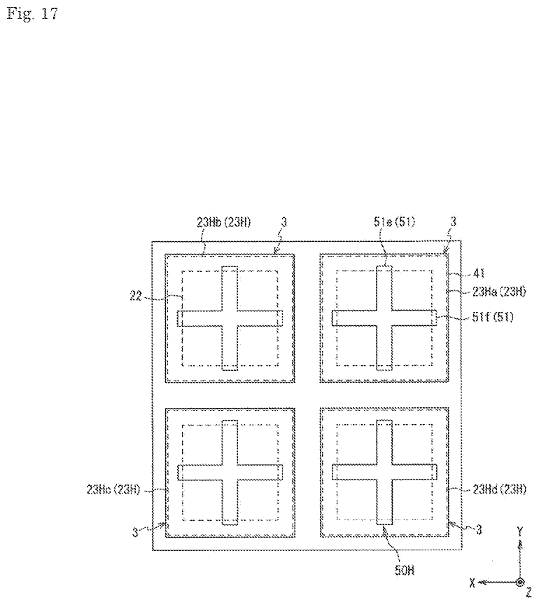

Modified Example 3 of the second embodiment of the present technology illustrated in FIG. 17 will be described below. A light detection device 1 according to this Modified Example 3 of the second embodiment is different from the light detection device 1 according to the second embodiment described above and the light detection device 1 according to Modified Example 2 of the second embodiment in that an uneven part 50H has two types of grooves 51 extending in different directions and has each one of the two types of grooves 51, and the other configurations of the light detection device 1 are basically similar to those of the light detection devices 1 according to the second embodiment described above and the Modified Example 2 of the second embodiment. The same reference signs will be assigned to constituent elements that have already been described, and description thereof will be omitted.

### <Photoelectric Conversion Area>

The light detection device 1 according to Modified Example 3 of the second embodiment includes a photoelectric conversion area 23H. A relation between the photoelectric conversion area 23H and the wire grid polarizer 60 is similar to that of the first embodiment, and the photoelectric conversion areas 23, 23a, 23b, 23c, and 23d illustrated in FIG. 5A may be rephrased as photoelectric conversion areas 23H, 23Ha, 23Hb, 23Hc, and 23Hd. In addition, as illustrated in FIG. 17, all the photoelectric conversion areas 23Ha, 23Hb, 23Hc, and 23Hd have the uneven parts 50H of the same shape.

### <Uneven Part>

The wire grid polarizer 60 side of the photoelectric conversion area 23H includes an uneven part 50H. In other words, the optical element side of the photoelectric conversion area 23H forms the uneven part 50H. The uneven part 50H includes grooves 51 extending in different directions. More specifically, the uneven part 50H includes one groove 51e and one groove 51f described in Modified Example 2 of the second embodiment described above. Each of the uneven part 50H of the photoelectric conversion area 23Ha, the uneven part 50H of the photoelectric conversion area 23Hb, the uneven part 50H of the photoelectric conversion area 23Hc, and the uneven part 50H of the photoelectric conversion area 23Hd has one groove 51e and one groove 51f.

In this way, each of the uneven parts 50H includes two types of grooves 51e and 51f extending in different directions. In this way, each of the uneven parts 50H may include at least two types of grooves 51e and 51f extending in different directions at least one of each type.

### <<Main Effect of Modified Example 3 of Second Embodiment>>

Also in the case of the light detection device 1 according to this Modified Example 3 of the second embodiment, effects similar to those of the light detection devices 1 according to the second embodiment and Modified Example 2 of the second embodiment described above can be acquired.

### Modified Example 4 of Second Embodiment

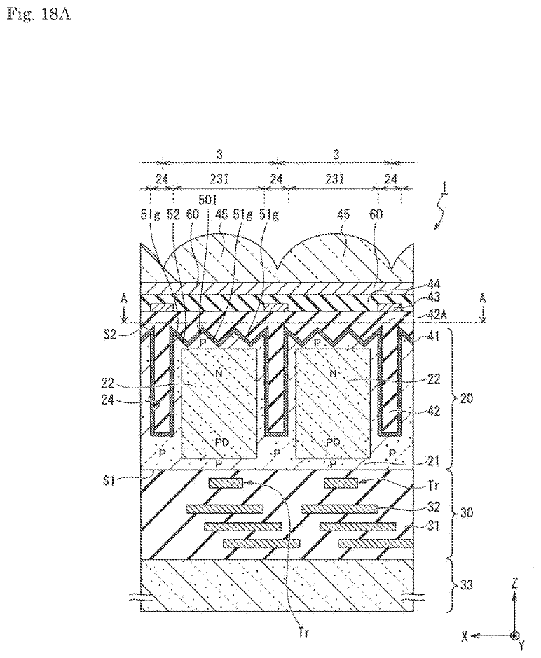

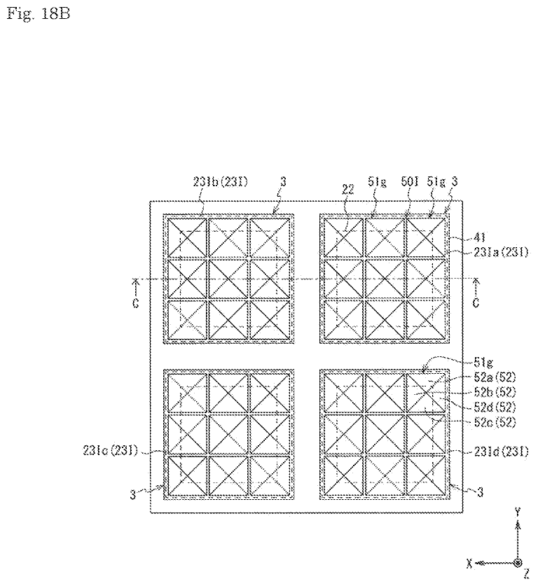

Modified Example 4 of the second embodiment of the present technology illustrated in FIGS. 18A and 18B will be described below. A light detection device 1 according to this Modified Example 4 of the second embodiment is different from the light detection device 1 according to the second embodiment described above in that an uneven part 50I has a concave part 51g in place of a groove, and the other configurations of the light detection device 1 are basically similar to those of the light detection device 1 according to the second embodiment described above. The same reference signs will be assigned to constituent elements that have already been described, and description thereof will be omitted.

### <Photoelectric Conversion Area>

FIG. 18B is a horizontal cross-sectional view illustrating a cross-section structure taken along cut-out line A-A illustrated in FIG. 18A. FIG. 18A is a longitudinal cross-sectional view illustrating a cross-section structure taken along cut-out line C-C illustrated in FIG. 18B. The light detection device 1 according to Modified Example 4 of the second embodiment has a photoelectric conversion area 23I. A relation between the photoelectric conversion area 23I and the wire grid polarizer 60 is similar to that of the first embodiment, and the photoelectric conversion areas 23, 23a, 23b, 23c, and 23d illustrated in FIG. 5A may be rephrased as photoelectric conversion areas 23I, 23Ia, 23Ib, 23Ic, and 23Id. In addition, as illustrated in FIG. 18B, all the photoelectric conversion areas 23Ia, 23Ib, 23Ic, and 23Id have the uneven parts 50I of the same shape.

### <Uneven Part>

The wire grid polarizer 60 side of the photoelectric conversion area 23I includes an uneven part 50I. In other words, the optical element side of the photoelectric conversion area 23I forms the uneven part 50I. The uneven part 50I has a plurality of concave parts (third concave parts) 51g.

More specifically, the uneven part 50I of each of the photoelectric conversion area 23Ia, the photoelectric conversion area 23Ib, the photoelectric conversion area 23Ic, and the photoelectric conversion area 23Id has a plurality of concave parts 51g disposed on the second face S2. In other words, the second face S2 has a shape having unevenness according to the concave parts 51g. FIG. 18B illustrates an example in which the uneven part 50I has a total of 9 concave parts 51g having three concave parts arranged in each of the X direction and the Y direction. The concave parts 51g are arranged in a matrix pattern in the X direction and the Y direction. In this way, the uneven part 50I of the photoelectric conversion area 23Ia, the uneven part 50I of the photoelectric conversion area 23Ib, the uneven part 50I of the photoelectric conversion area 23Ic, and the uneven part 50I of the photoelectric conversion area 23Id, have the same shape.

In addition, as illustrated in FIGS. 18A and 18B, each concave part 51g has a shape acquired by vertically reversing a square pyramid and has four inclined faces 52a, 52b, 52c, and 52d. Each of the inclined faces 52a, 52b, 52c, and 52d is a face inclined with respect to a thickness direction of the semiconductor layer 20. In a case in which the inclined faces 52a, 52b, 52c, and 52d do not need to be identified from each other, each thereof will be simply referred to as an inclined face 52 without the inclined faces 52a, 52b, 52c, and 52d being identified from each other.

### <<Main Effect of Modified Example 4 of Second Embodiment>

Also in the case of the light detection device 1 according to this Modified Example 4 of the second embodiment, effects similar to those of the light detection devices 1 according to the second embodiment described above can be acquired.

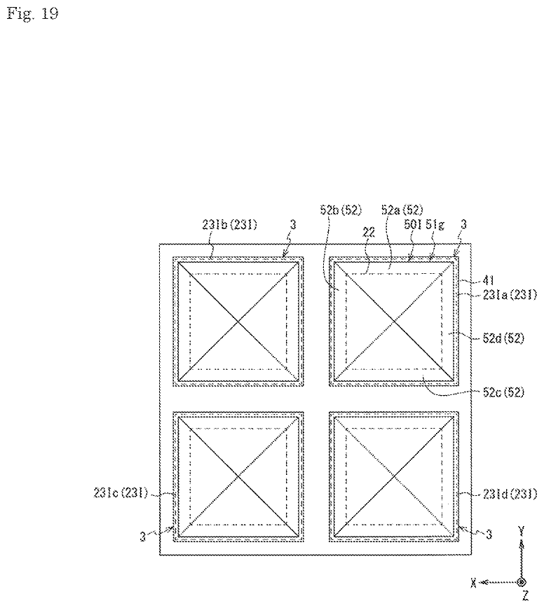

In addition, although the uneven part 50I has been described to have a plurality of concave parts 51g, as illustrated in FIG. 19, only one concave part 51g may be included therein. In such a case, the size of the concave part 51g may be larger than that of a case in which a plurality of concave parts are included.

### Third Embodiment

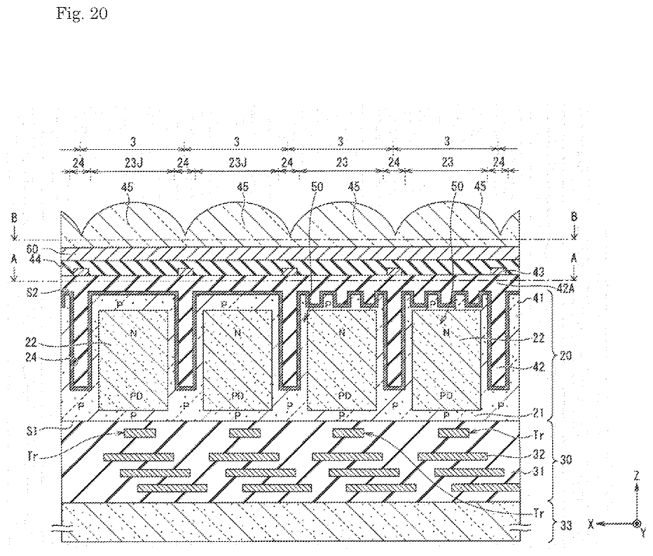

A third embodiment of the present technology illustrated in FIGS. 20 to 22 will be described below. A light detection device 1 according to this third embodiment is different from the light detection device 1 according to the first embodiment described above in that a photoelectric conversion area 23 and a photoelectric conversion area 23J of which a quantum efficiency is lower than that of the photoelectric conversion area 23, and the other configurations of the light detection device 1 are basically similar to those of the light detection device 1 according to the first embodiment described above. The same reference signs will be assigned to constituent elements that have already been described, and description thereof will be omitted.

### <Wire Grid Polarizer>

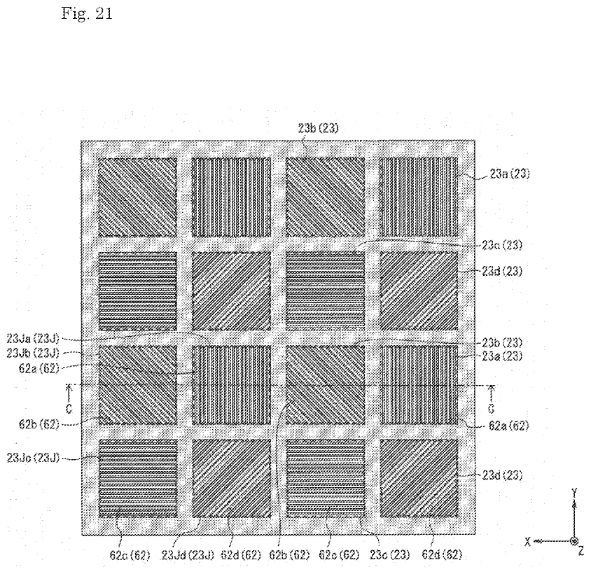

As illustrated in FIG. 21, a wire grid polarizer 60 has a plurality of sets of groove formation areas 62a, 62b, 62c, and 62d.

### <Photoelectric Conversion Area>

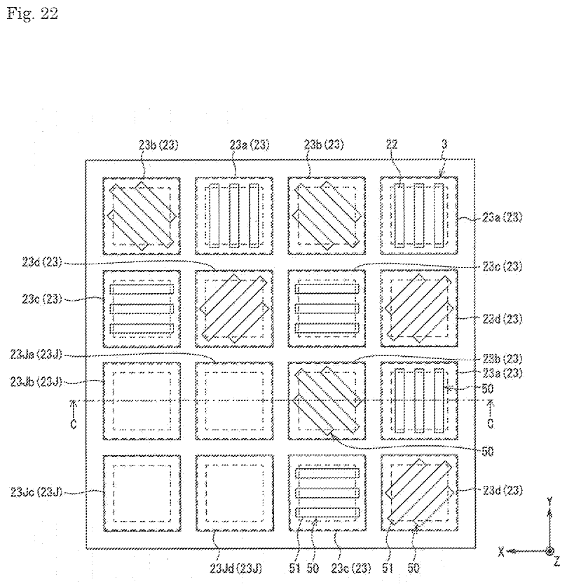

The light detection device 1 according to the third embodiment includes photoelectric conversion areas 23 and 23J. As illustrated in FIG. 21, the photoelectric conversion areas 23 and 23J overlap a different set of the wire grid polarizer 60 in the plan view. As illustrated in FIGS. 20 and 22, while the photoelectric conversion area 23 has an uneven part 50, the photoelectric conversion area 23J does not have the uneven part 50. The photoelectric conversion area 23J is an example of a third photoelectric conversion area of which a quantum efficiency is lower than that of the first photoelectric conversion area and the second photoelectric conversion area.

As illustrated in FIGS. 21 and 22, a photoelectric conversion area overlapping the groove formation area 62a in the plan view among photoelectric conversion areas 23J will be referred to as a photoelectric conversion area 23Ja for identifying it from the other photoelectric conversion areas. Similarly, among photoelectric conversion areas 23J, a photoelectric conversion area overlapping the groove formation area 62b in the plan view will be referred to as a photoelectric conversion area 23Jb, a photoelectric conversion area overlapping the groove formation area 62c in the plan view will be referred to as a photoelectric conversion area 23Jc, and a photoelectric conversion area overlapping the groove formation area 62d in the plan view will be referred to as a photoelectric conversion area 23Jd. All the photoelectric conversion areas 23Ja, 23Jb, 23Jc, and 23Jd do not have an uneven part 50. In addition, in a case in which these photoelectric conversion areas 23Ja, 23Jb, 23Jc, and 23Jd do not need to be identified from each other, each thereof will be simply referred to as a photoelectric conversion area 23J.

The photoelectric conversion area 23J does not have the uneven part 50, and thus the quantum efficiency thereof is lower than the quantum efficiency of the photoelectric conversion area 23. In other words, the sensitivity of the photoelectric conversion area 23J becomes lower than the sensitivity of the photoelectric conversion area 23. In this way, the semiconductor layer 20 has the photoelectric conversion area 23J that overlaps the wire grid polarizer 60 in the plan view and has quantum efficiency to be lower than that of the photoelectric conversion area 23.

### <<Main Effect of Third Embodiment>

Also in the case of the light detection device 1 according to this third embodiment, effects similar to those of the light detection device 1 according to the first embodiment described above can be acquired.

In addition, the light detection device 1 according to this third embodiment includes both the photoelectric conversion area 23 and the photoelectric conversion area 23J of which the quantum efficiency is lower than that of the photoelectric conversion area 23, and thus a dynamic range of the light detection device 1 can be widened. More specifically, by performing a calculation process based on a sensitive difference between the photoelectric conversion area 23 and the photoelectric conversion area 23J, the dynamic range of the light detection device 1 can be widened.

In the light detection device 1 according to this third embodiment, although the photoelectric conversion area 23J is configured not to have the uneven part 50, the configuration is not limited thereto. The photoelectric conversion area 23J may have an uneven part of which the quantum efficiency (sensitivity) is lower than that of the uneven part 50 described above, for example, the uneven part 50A.

### Fourth Embodiment

### <Application Example to Electronic Apparatus>

Next, an electronic apparatus according to a fourth embodiment of the present technology illustrated in FIG. 23 will be described. The electronic apparatus 100 according to the fourth embodiment includes a light detection device (a solid-state imaging device) 101, an optical lens 102, a shutter device 103, a drive circuit 104, and a signal processing circuit 105. The electronic apparatus 100 according to the fourth embodiment illustrates an embodiment of a case in which any one of the light detection devices 1 described above is used in an electronic apparatus (for example, a camera) as the light detection device 101.

The optical lens (an optical system) 102 forms image light (incident light 106) from a subject as an image on an imaging surface of the light detection device 101. In accordance with this, a signal electric charge is accumulated over a predetermined period inside the light detection device 101. The shutter device 103 controls a light emission period and a light shielding period for the light detection device 101. The drive circuit 104 supplies drive signals for controlling a transmission operation of the light detection device 101 and a shutter operation of the shutter device 103. In accordance with a drive signal (timing signal) supplied from the drive circuit 104, signal transmission of the light detection device 101 is performed. The signal processing circuit 105 performs various types of signal processing on a signal (a pixel signal) output from the light detection device 101. An image signal having been subjected to signal processing is stored in a storage medium such as a memory or output to a monitor.

In accordance with such a configuration, the electronic apparatus 100 according to the fourth embodiment can supplement lowering of sensitivity of the light detection device 101, and thus improvement of image quality of an image signal can be achieved.

In addition, an electronic apparatus 100 to which the light detection device 1 according to any one of the first to third embodiments and the modified examples thereof can be applied is not limited to a camera, and the light detection device 1 can be applied to other electronic apparatuses. For example, the electronic apparatus 100 may be applied to an imaging device such as a camera module for a mobile device such as a mobile phone.

In addition, in the fourth embodiment, as the light detection device 101, the light detection device 1 according to a combination of at least two of the first to third embodiments and the modified examples thereof can be used in an electronic apparatus.

### OTHER EMBODIMENTS

As described above, while the present technology has been described with reference to the first to fourth embodiments, the description and the drawings forming a part of the present disclosure should not be construed as limiting the present technology. Various alternative embodiments, examples, and operable techniques will be apparent to those skilled in the art from the present disclosure.

For example, technical ideas described in the first to fourth embodiments may be combined together. For example, although the light detection device 1 according to Modified Example 4 of the first embodiment includes the concave part group 51D in place of the groove 51, various combinations according to technical ideas thereof can be formed, for example, by applying such a technical idea to the light detection devices 1 according to other modified examples of the first embodiment, the second embodiment and the modified examples thereof, the third embodiment, and the like.

In addition, in the embodiments described above and the modified examples thereof, although the wire grid polarizer 60 includes four types of groove formation areas 62a, 62b, 62c, and 62d, the configuration is not limited thereto. The wire grid polarizer 60 may include at least two types of groove formation areas. In addition, also the arrangement direction of the groove 63 of the groove formation area 62 is not limited to the directions illustrated in the embodiments described above and the modified examples thereof. Furthermore, in the embodiments described above and the modified examples thereof, although the first area has been described as the groove formation area 62a, and the second area has been described as the groove formation area 62b, the configuration is not limited thereto. The first area and the second area may be different types of groove formation areas and may be areas other than the groove formation areas 62a and 62b or may be areas other than the groove formation areas of types other than those described in the embodiments described above. In addition, the first direction and the second direction may be directions different from each other and are not limited to the directions illustrated in the embodiments described above.

In the embodiments described above, although the first angle is an angle that has advanced counterclockwise from the arrangement direction of the groove 63 disposed in the groove formation area 62, it may be an angle that has advanced clockwise. The first angle may be an angle that has advanced counterclockwise or an angle that has advanced counterclockwise as along as it is an angle that has advanced in the same direction with respect to the first direction and the second direction.

In addition, the light detection device 1 may be a lamination-type CMOS image sensor (CIS) in which two or more semiconductor substrates are stacked with overlapping each other. In such a case, at least one of the logic circuit 13 and the reading circuit 15 may be disposed in a substrate different from a semiconductor substrate in which the photoelectric conversion area 23 is disposed among the semiconductor substrates.

In addition, the present technology can be applied to a general light detection device including a distance measuring sensor measuring a distance also called a time of flight (ToF) sensor and the like in addition to a solid-state imaging device as an image sensor. The distance measuring sensor is a sensor that emits irradiation light to an object, detects reflective light acquired by reflecting the irradiation light on the surface of the object and has returned, and calculates a distance to the object on the basis of a flight time until the reflective light is received after emission of the irradiation light. As a light receiving pixel structure of this distance measuring sensor, the structure of the pixel 3 described above can be employed.

In this manner, it is apparent that the present technology includes various embodiments and the like that are not described herein. Therefore, the technical scope of the present technology is to be determined solely by matters specifying the invention according to the scope of claims that is reasonable from the description presented above.

Furthermore, the effects described in the present specification are merely exemplary and not intended as limiting, and other advantageous effects may be produced.

Here, the present technology may have the following configurations.

(1)

A light detection device including a semiconductor layer having a photoelectric conversion area; and an optical element including a base material and a plurality of opening parts disposed in the base material and having a groove shape passing through the base material in a thickness direction, selecting light having a polarization plane along an arrangement direction of the opening parts, supplying the selected light to the photoelectric conversion area, and disposed to overlap the photoelectric conversion area in a plan view, in which the opening parts are aligned in a longitudinal direction and are disposed to be separated from each other in a transverse direction, the optical element includes a first area in which the opening parts are arranged in a first direction and a second area in which the opening parts are arranged in a second direction different from the first direction, the optical element side of the photoelectric conversion area has an uneven part, the uneven part of a first photoelectric conversion area that is the photoelectric conversion area overlapping the first area in a plan view includes a plurality of concave parts arranged in a direction forming a first angle with the first direction or a groove extending in this direction, and the uneven part of a second photoelectric conversion area that is the photoelectric conversion area overlapping the second area in the plan view includes a plurality of concave parts arranged in a direction forming the first angle with the second direction or a groove extending in this direction.

(2)

The light detection device described in (1), in which the first angle is 90 degrees.

(3)

The light detection device described in (1), in which the first angle is 0 degrees.

(4)

The light detection device described in (1), in which the first angle is 45 degrees or 135 degrees.

(5)

The light detection device described in (1), in which the first angle is in the range of #5 degrees from 90 degrees as its center.

(6)

The light detection device described in (1), in which the first angle is in the range of ±5 degrees from 0 degrees as its center.

(7)

The light detection device described in (1), in which the first angle is in the range of ±5 degrees from 45 degrees as its center or the range of ±5 degrees from 135 degrees as its center.

(8)

The light detection device described in any one of (1) to (7), in which the first uneven part and the second uneven part include both the plurality of concave parts arranged in a direction forming the first angle with the first direction or the grooves extending in this direction and the plurality of concave parts arranged in a direction forming the first angle with the second direction or the grooves extending in this direction.

(9)

The light detection device described in (8), in which the first uneven part and the second uneven part have the same shape.

(10)

The light detection device described in any one of (1) to (9), in which the semiconductor layer overlaps the optical element in the plan view and has a third photoelectric conversion area of which a quantum efficiency is lower than that of the first photoelectric conversion area and the second photoelectric conversion area.

(11)

The light detection device described in (10), in which the third photoelectric conversion area does not have the uneven parts.

(12)

The light detection device described in any one of (1) to (11), in which the optical element contains a metal.

(13)

The light detection device described in (12), in which the optical element is a wire grid polarizer.

(14)

The light detection device described in any one of (1) to (13), in which the optical element side of the photoelectric conversion area has the uneven parts.

(15)

An electronic apparatus including a light detection device; and an optical system configured to form an image of image light from a subject in the light detection device, in which the light detection device includes a semiconductor layer having a photoelectric conversion area; and an optical element including a base material and a plurality of opening parts disposed in the base material and having a groove shape passing through the base material in a thickness direction, selecting light having a polarization plane along an arrangement direction of the opening parts, supplying the selected light to the photoelectric conversion area, and disposed to overlap the photoelectric conversion area in a plan view, the opening parts are aligned in a longitudinal direction and are disposed to be separated from each other in a transverse direction, the optical element includes a first area in which the opening parts are arranged in a first direction and a second area in which the opening parts are arranged in a second direction different from the first direction, a light incidence face of the semiconductor layer has a plurality of uneven parts, a first uneven part that is the uneven part included in a first photoelectric conversion area that is the photoelectric conversion area overlapping the first area in the plan view includes a plurality of concave parts arranged in a direction forming a first angle with the first direction or grooves extending in this direction, and a second uneven part that is the uneven part included in a second photoelectric conversion area that is the photoelectric conversion area overlapping the second area in the plan view includes a plurality of concave parts arranged in a direction forming the first angle with the second direction or grooves extending in this direction.

### REFERENCE SIGNS LIST

1 Light detection device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
15 Reading circuit
20 Semiconductor layer
23 Photoelectric conversion area
24 Isolation groove
21 Well region
1 Light detection device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Reading circuit
20 Semiconductor layer
23 Photoelectric conversion area
24 Isolation groove
21 Well region
22 Photoelectric conversion unit
23, 23A, 23B, 23C, 23D, 23E, 23F, 23G, 23H, 23I, 23J Photoelectric Conversion area
24 Isolation groove
30 Multilayer wiring layer
31 Interlayer insulating film
32 Wiring layer
33 Support substrate
41 Pinning layer
42 Isolation area
43 Light shielding layer
44 Planarization film
45 Micro-lens
50, 50A, 50B, 50C, 50D, 50E, 50F, 50G, 50H, 50I Uneven part
51, 51a, 51b, 51c, 51d, 51e, 51f Groove
51F, 51g Concave part
51D Concave part group
51Da Concave part
60 Wire grid polarizer
61 Base material
62, 62a, 62b, 62c, 62d Groove formation area
63 Groove
64 Band-shaped conductor
65 Planarization film
100 Electronic apparatus
101 Light detection device
102 Optical system (optical lens)
102 Optical system
102 Optical lens (optical system)
102 Optical lens
103 Shutter device
104 Drive circuit
105 Signal processing circuit
106 Incident light

What is claimed is:

1. A light detection device, comprising:
a semiconductor layer having a photoelectric conversion area; and
an optical element including a base material and a plurality of opening parts disposed in the base material and having a groove shape passing through the base material in a thickness direction, selecting light having a polarization plane along an arrangement direction of the opening parts, supplying the selected light to the photoelectric conversion area, and disposed to overlap the photoelectric conversion area in a plan view,
wherein the opening parts are aligned in a longitudinal direction and are disposed to be separated from each other in a transverse direction,
wherein the optical element includes a first area in which the opening parts are arranged in a first direction and a second area in which the opening parts are arranged in a second direction different from the first direction,
wherein a light incidence face of the semiconductor layer has a plurality of uneven parts,
wherein a first uneven part that is the uneven part included in a first photoelectric conversion area that is the photoelectric conversion area overlapping the first area in the plan view includes a plurality of concave parts arranged in a direction forming a first angle with the first direction or grooves extending in this direction, and
wherein a second uneven part that is the uneven part included in a second photoelectric conversion area that is the photoelectric conversion area overlapping the second area in the plan view includes a plurality of concave parts arranged in a direction forming the first angle with the second direction or grooves extending in this direction.

2. The light detection device according to claim 1, wherein the first angle is 90 degrees.

3. The light detection device according to claim 1, wherein the first angle is 0 degrees.

4. The light detection device according to claim 1, wherein the first angle is 45 degrees or 135 degrees.

5. The light detection device according to claim 1, wherein the first angle is in the range of ±5 degrees from 90 degrees as its center.

6. The light detection device according to claim 1, wherein the first angle is in the range of ±5 degrees from 0 degrees as its center.

7. The light detection device according to claim 1, wherein the first angle is in the range of ±5 degrees from 45 degrees as its center or the range of ±5 degrees from 135 degrees as its center.

8. The light detection device according to claim 1, wherein the first uneven part and the second uneven part include both the plurality of concave parts arranged in a direction forming the first angle with the first direction or the grooves extending in this direction and the plurality of concave parts arranged in a direction forming the first angle with the second direction or the grooves extending in this direction.

9. The light detection device according to claim 8, wherein the first uneven part and the second uneven part have the same shape.

10. The light detection device according to claim 1, wherein the semiconductor layer overlaps the optical element in the plan view and has a third photoelectric conversion area of which a quantum efficiency is lower than that of the first photoelectric conversion area and the second photoelectric conversion area.

11. The light detection device according to claim 10, wherein the third photoelectric conversion area does not have the uneven parts.

12. The light detection device according to claim 1, wherein the optical element contains a metal.

13. The light detection device according to claim 12, wherein the optical element is a wire grid polarizer.

14. The light detection device according to claim 1, wherein the optical element side of the photoelectric conversion area has the uneven parts.

15. An electronic apparatus, comprising:
a light detection device; and
an optical system configured to form an image of image light from a subject in the light detection device,
wherein the light detection device includes:
a semiconductor layer having a photoelectric conversion area; and
an optical element including a base material and a plurality of opening parts disposed in the base material and having a groove shape passing through the base material in a thickness direction, selecting light having a polarization plane along an arrangement direction of the opening parts, supplying the selected light to the photoelectric conversion area, and disposed to overlap the photoelectric conversion area in a plan view,
wherein the opening parts are aligned in a longitudinal direction and are disposed to be separated from each other in a transverse direction,
wherein the optical element includes a first area in which the opening parts are arranged in a first direction and a second area in which the opening parts are arranged in a second direction different from the first direction,
wherein a light incidence face of the semiconductor layer has a plurality of uneven parts,
wherein a first uneven part that is the uneven part included in a first photoelectric conversion area that is the photoelectric conversion area overlapping the first area in the plan view includes a plurality of concave parts arranged in a direction forming a first angle with the first direction or grooves extending in this direction, and
wherein a second uneven part that is the uneven part included in a second photoelectric conversion area that is the photoelectric conversion area overlapping the second area in the plan view includes a plurality of concave parts arranged in a direction forming the first angle with the second direction or grooves extending in this direction.
